(19) United States
(12) Patent Application Publication
(10) Pub. No.: US 2025/0359161 A1
(43) Pub. Date: Nov. 20, 2025

(54) DEVICE PERFORMANCE DIVERSIFICATION

(71) Applicant: Taiwan Semiconductor Manufacturing Company, Ltd., Hsinchu (TW)

(72) Inventors: Shu-Wei Wang, Taichung City (TW); Hsin Yang Hung, New Taipei City (TW); Wei-Xiang You, Kaohsiung City (TW); Jui-Chien Huang, Hsinchu City (TW); Szuya Liao, Hsinchu (TW)

(21) Appl. No.: 19/281,185

(22) Filed: Jul. 25, 2025

Related U.S. Application Data
(63) Continuation of application No. 18/505,668, filed on Nov. 9, 2023.

(51) Int. Cl. H10D 30/67; H10D 30/01; H10D 30/43; H10D 62/10; H10D 62/13; H10D 64/01; H10D 84/01; H10D 84/03; H10D 84/83

(52) U.S. Cl. CPC H10D 30/6735; H10D 30/014; H10D 30/43; H10D 30/6757; H10D 62/121; H10D 62/151; H10D 64/017; H10D 84/013; H10D 84/0149; H10D 84/038; H10D 84/83

(57) ABSTRACT

Semiconductor structures and methods are provided. A semiconductor structure according to the present disclosure includes a substrate, a first semiconductor layer over the substrate, a second semiconductor layer over the first semiconductor layer and including a channel region sandwiched between a first source/drain region and a second source/drain region, a first plurality of nanostructures disposed over the channel region, a first leakage block layer over the first source/drain region, a second leakage block layer over the second source/drain region, a dielectric layer on the first leakage block layer, a first source/drain feature on the dielectric layer and in contact with first sidewalls of the first plurality of nanostructures, and a second source/drain feature disposed on the second leakage block layer and in contact with second sidewalls of the first plurality of nanostructures. The first leakage block layer and the second leakage block layer includes an undoped semiconductor material.

### PRIORITY DATA

This application is a continuation application of U.S. patent application Ser. No. 18/505,668, filed Nov. 9, 2023, which is hereby incorporated by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

For example, as integrated circuit (IC) technologies progress towards smaller technology nodes, multi-gate devices have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Fin-like field effect transistors (FinFETs) and multi-bridge-channel (MBC) transistors are examples of multi-gate devices that have become popular and promising candidates for high performance and low leakage applications. A FinFET has an elevated channel wrapped by a gate on more than one side (for example, the gate wraps a top and sidewalls of a “fin” of semiconductor material extending from a substrate). An MBC transistor has a gate structure that can extend, partially or fully, around a channel region to provide access to the channel region on two or more sides. Because its gate structure surrounds the channel regions, an MBC transistor may also be referred to as a surrounding gate transistor (SGT) or a gate-all-around (GAA) transistor. The channel region of an MBC transistor may be formed from nanowires, nanosheets, other nanostructures, and/or other suitable structures. The shapes of the channel region have also given an MBC transistor alternative names such as a nanosheet transistor or a nanowire transistor.

As the semiconductor industry further progresses into sub-10 nanometer (nm) technology process nodes in pursuit of higher device density, higher performance, and lower costs, challenges from both fabrication and design issues have led to stacked device structure configurations, such as complementary field effect transistors (C-FET) where an n-type multi-gate transistor and a p-type multi-gate transistor are stacked vertically, one over the other. While existing C-FET structures and fabrication processes are generally adequate for their intended purposes, they are not satisfactory in all aspects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flow chart of a method 100 for forming a semiconductor device having a vertical C-FET structure, according to one or more aspects of the present disclosure.

FIGS. 2A, 3A, 4A, 5A, 6A, 7A, 8A, 9A, 10A, 11A, 12A, and 13A, (2A-13A) and 2B, 3B, 4B, 5B, 6B, 7B, 8B, 9B, 10B, 11B, 12B, and 13B (2B-13B) illustrate fragmentary cross-sectional views of a workpiece undergoing various fabrication processes in the method of FIG. 1, according to one or more aspects of the present disclosure.

FIG. 14 illustrates a flow chart of a method 300 for forming a semiconductor device having a vertical C-FET structure, according to one or more aspects of the present disclosure.

FIGS. 15A, 16A, 17A, 18A, 19A, and 20A (15A-20A) and 15B, 16B, 17B, 18B, 19B, and 20B (15B-20B) illustrate fragmentary cross-sectional views of a workpiece undergoing various fabrication processes in the method of FIG. 14, according to one or more aspects of the present disclosure.

FIG. 21 illustrates a flow chart of a method 500 for forming a semiconductor device having a vertical C-FET structure, according to one or more aspects of the present disclosure.

FIGS. 22-31 illustrate fragmentary cross-sectional views of a workpiece undergoing various fabrication processes in the method of FIG. 21, according to one or more aspects of the present disclosure.

FIG. 32 illustrates a flow chart of a method 700 for forming a semiconductor device having a vertical C-FET structure, according to one or more aspects of the present disclosure.

FIGS. 33A, 34A, 35A, 36A, 37A, and 38A (33A-38A) and 33B, 34B, 35B, 36B, 37B, and 38B (33B-38B) illustrate fragmentary cross-sectional views of a workpiece undergoing various fabrication processes in the method of FIG. 32, according to one or more aspects of the present disclosure.

FIG. 39 illustrates a flow chart of a method 900 for forming a semiconductor device having a vertical C-FET structure, according to one or more aspects of the present disclosure.

FIGS. 40-52 illustrate fragmentary cross-sectional views of a workpiece undergoing various fabrication processes in the method of FIG. 39, according to one or more aspects of the present disclosure.

FIG. 53 illustrates a flow chart of a method 1000 for forming a semiconductor device having a vertical C-FET structure, according to one or more aspects of the present disclosure.

FIGS. 54A, 54B, 55A, 55B, 56A, 56B, 57, 58A, 58B, 59A, 59B, 60A, and 60B illustrate fragmentary cross-sectional views of a workpiece undergoing various fabrication processes in the method of FIG. 53, according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

A stacked multi-gate device refers to a semiconductor device that includes a bottom multi-gate device and a top multi-gate device stacked over the bottom multi-gate device. When the bottom multi-gate device and the top multi-gate device are of different conductivity types, the stacked multi-gate device may be a complementary field effect transistor (C-FET). The multi-gate devices in a C-FET may be FinFETs or MBC transistors. In some circuit applications, performance is optimized when a portion of the devices have an operation speed faster than that of another portion of the devices. For example, in some static random access memory (SRAM) applications that do not come with any write-assist designs, the performance of an SRAM cell is not optimal unless an on-state current of some p-type devices is smaller than that of n-type devices. In some instances, the performance of an SRAM cell may be improved when an on-state current of some p-type devices is about one-half of that of n-type devices.

The present disclosure provides multiple methods of fabricating transistors of different performance attributes in a C-FET transistor construction. In one embodiment, a dielectric layer is selectively deposited over a semiconductor surface on which a source/drain feature is epitaxially grown to modify the amount of strain exerted on the channel. In another embodiment, a dielectric layer is selectively deposited to block epitaxial formation of a portion of a source/drain feature. In still another embodiment, process steps are designed such that bottom channel members and top channel members in a C-FET have different channel width to provide different performance. In yet another embodiment, a portion of a bottom transistor, including its channel region and gate structure, is trimmed to have a smaller channel width. In a further embodiment, bottom transistors and top transistors may include more than one channel widths. The different embodiments may be implemented individually or together to provide devices of a variety of performance attributes.

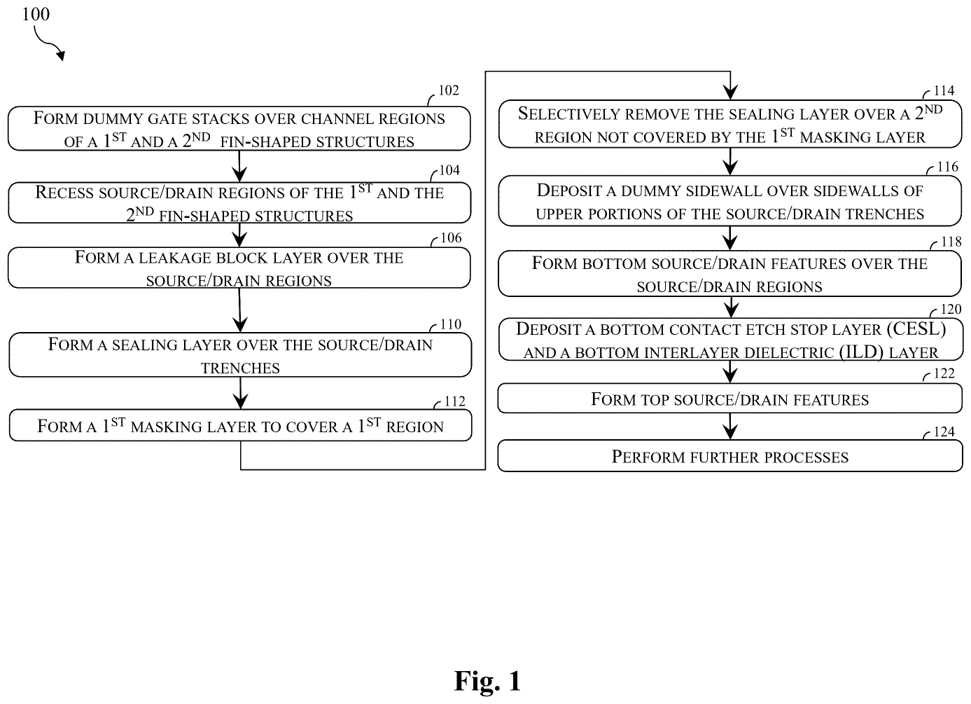

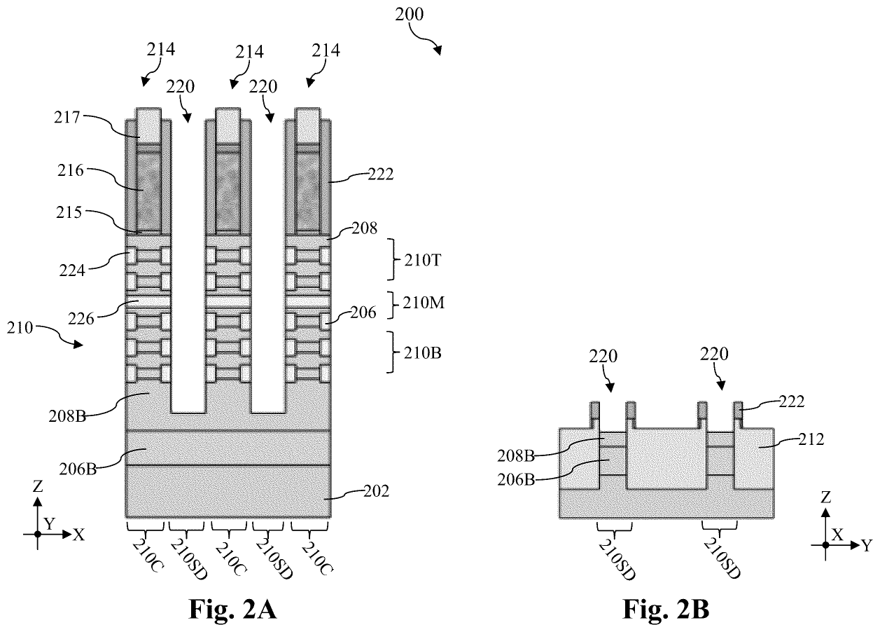

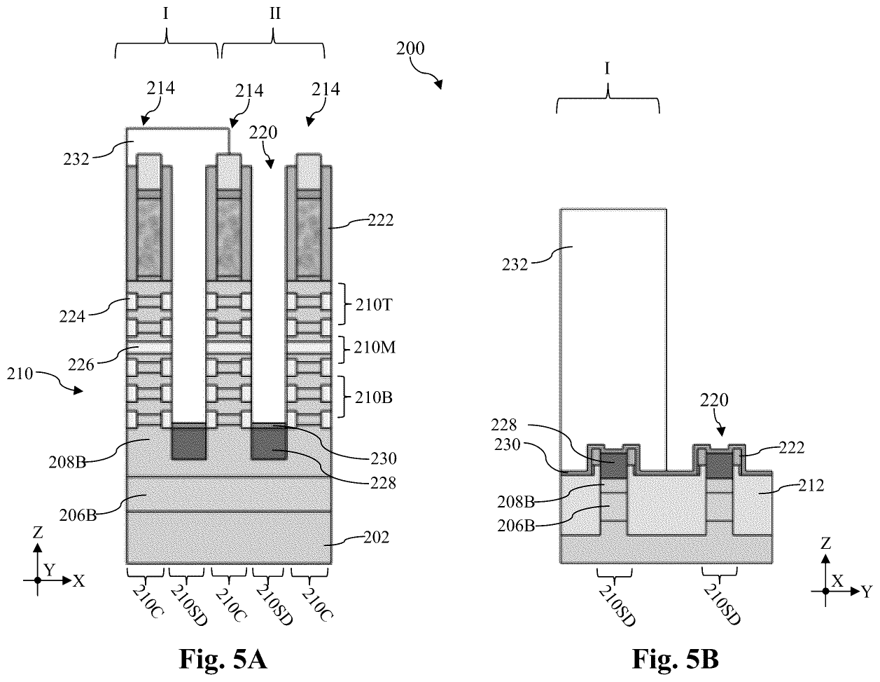

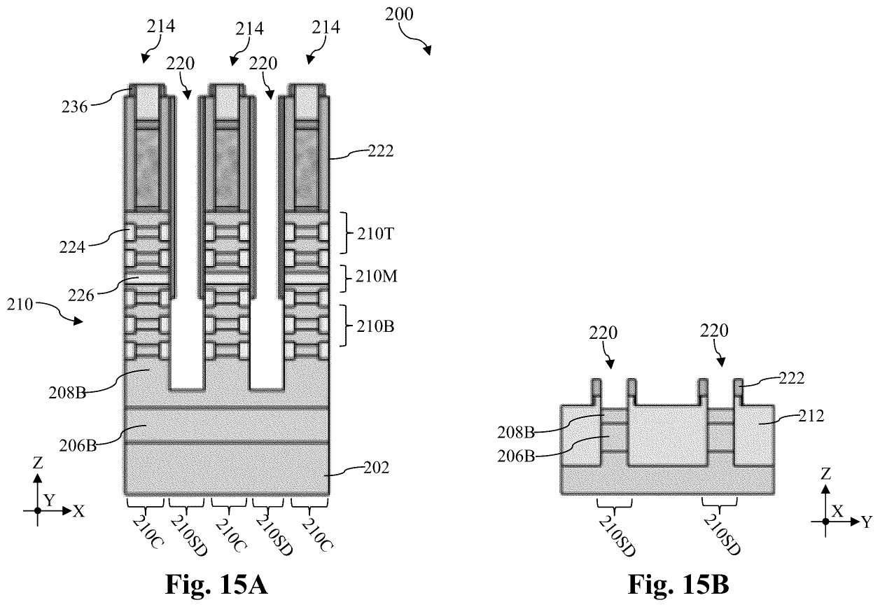

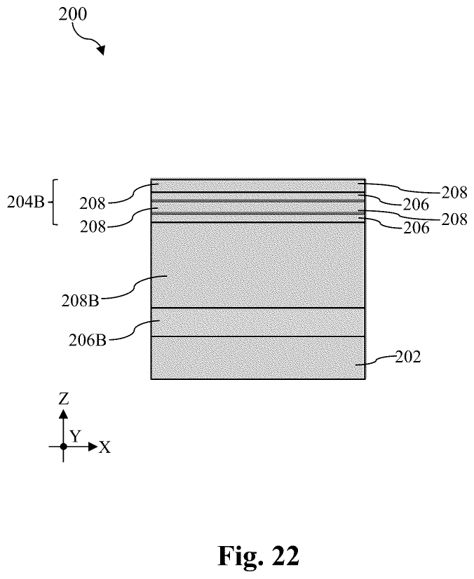

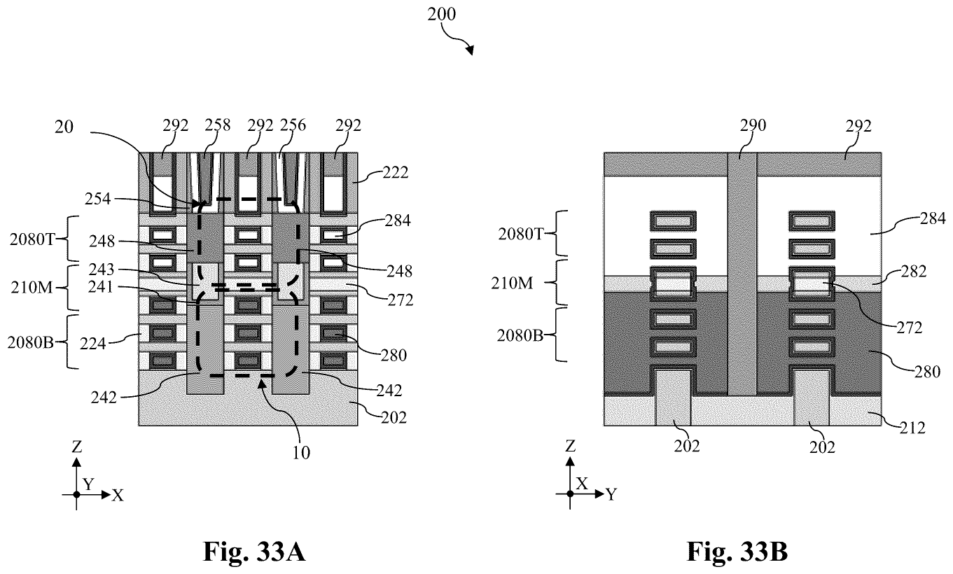

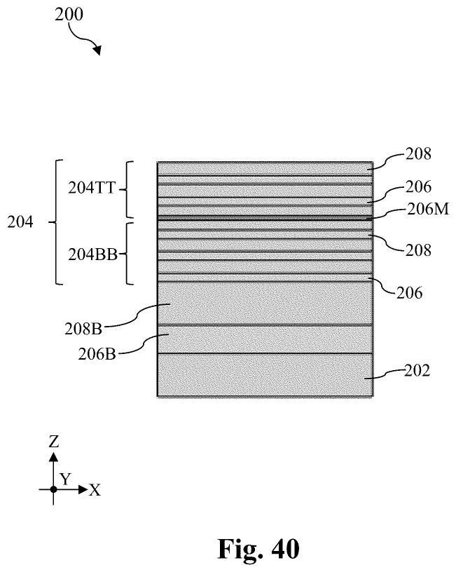

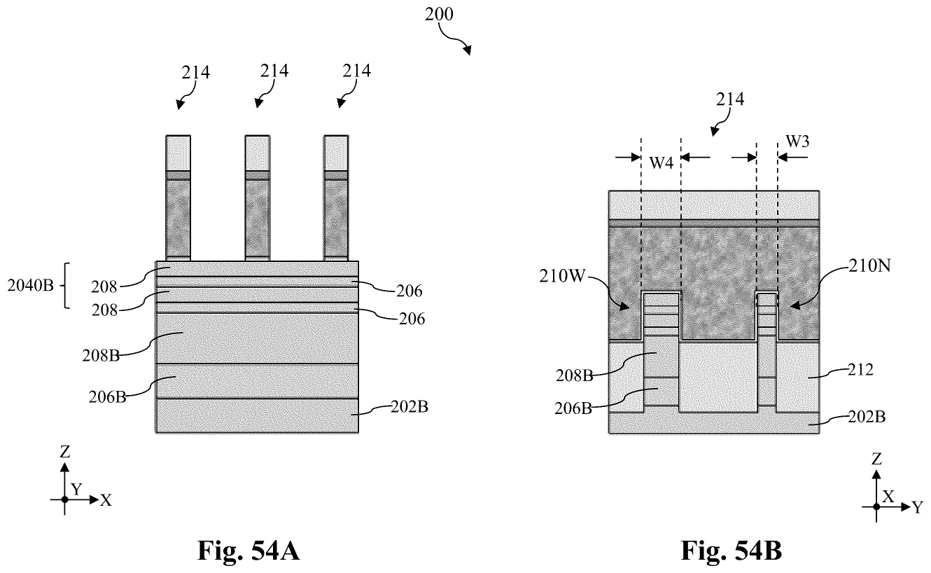

The various aspects of the present disclosure will now be described in more detail with reference to the figures. In that regard, FIGS. 1, 14, 21, 32, 39, and 53 are flowcharts illustrating method 100, method 300, method 500, method 700, method 900 and method 1000 for forming a semiconductor device according to various aspects of the present disclosure. Methods 100, 300, 500, 700, 900, and 1000 are merely examples and are not intended to limit the present disclosure to what is explicitly illustrated in methods 100, 300, 500, 700, 900, and 1000. Additional steps may be provided before, during and after method 100, 300, 500, 700, 900, and 1000, and some steps described can be replaced, eliminated, or moved around for additional embodiments of the method. Not all steps are described herein in detail for reasons of simplicity. Method 100 is described below in conjunction with FIGS. 2A-13A and 2B-13B, which are fragmentary cross-sectional views of a workpiece 200 at different stages of fabrication according to embodiments of method 100. Method 300 is described below in conjunction with FIGS. 15A-20A and 15B-20B, which are fragmentary cross-sectional views of a workpiece 200 at different stages of fabrication according to embodiments of method 100. Method 500 is described below in conjunction with FIGS. 22-31, which are fragmentary cross-sectional views of a workpiece 200 at different stages of fabrication according to embodiments of method 100. Method 700 is described below in conjunction with FIGS. 33A-38A and 33B-38B, which are fragmentary cross-sectional views of a workpiece 200 at different stages of fabrication according to embodiments of method 100. Method 900 is described below in conjunction with FIGS. 40-52, which are fragmentary cross-sectional views of a workpiece 200 at different stages of fabrication according to embodiments of method 100. Method 1000 is described below in conjunction with FIGS. 54A, 54B, 55A, 55B, 56A, 56B, 57, 58A, 58B, 59A, 59B, 60A, and 60B, which are fragmentary cross-sectional views of a workpiece 200 at different stages of fabrication according to embodiments of method 100. Because the workpiece 200 will be fabricated into a semiconductor device 200 upon conclusion of the fabrication processes, the workpiece 200 may be referred to as the semiconductor device 200 as the context requires. Additionally, throughout the present application and across different embodiments, like reference numerals denote like features with similar structures and compositions, unless otherwise excepted. Source/drain region(s) may refer to a source or a drain, individually or collectively dependent upon the context.

Method 100 forms a C-FET where source/drain features of bottom multi-gate device are epitaxially grown in different environments to strain channel differently.

Referring to FIGS. 1, 2A and 2B, method 100 includes a block 102 where dummy gate stacks 214 are formed over channel regions 210C of a first fin-shaped structure 210 and a second fin-shaped structure 210. FIGS. 2A and 2B illustrate two fragmentary cross-sectional views of a workpiece 200. Referring to FIG. 2A, the workpiece 200 includes a substrate 202, a bottom silicon germanium (SiGe) layer 206B disposed over the substrate 202, and a bottom silicon (Si) layer 208B disposed over the bottom SiGe layer 206B. The workpiece 200 further includes a fin-shaped structure 210. The fin-shaped structure 210 includes a bottom portion 210B, a middle portion 210M, and a top portion 210T. Each of the bottom portion 210B and the top portion 210T includes a plurality of channel layers 208 interleaved by a plurality of sacrificial layers 206. The middle portion 210M includes two channel layers 208 sandwiching a middle dielectric layer 226. The fin-shaped structure 210 includes channel regions 210C and source/drain regions 210SD interleaving the channel regions 210C. FIG. 2B provides an X-direction cross-sectional view across one of the source/drain regions 210SD. Because FIG. 2A illustrates a fin-shaped structure 210 where its source/drain regions 210SD are anisotropically recessed to form source/drain trenches 220, a substantial portion of the fin-shaped structure 210 is not shown in FIG. 2B, as it has been removed. The channel layers 208 in the bottom portion 210B and the top portion 210T are vertically interleaved by inner spacer features 224. Put differently, along the channel length direction (i.e., the X direction), each of the sacrificial layers 206 in the bottom portion 210B and the top portion 210T are end-capped by inner spacer features 224. At block 102, a dummy gate stack 214 is formed over each of the channel regions 210C. Before the source/drain regions 210SD are recessed to form the structure shown in FIGS. 2A and 2B, a gate spacer 222 is deposited over the workpiece 200. After the source/drain recessing process, the gate spacer 222 remains disposed along sidewalls of the dummy gate stack 214. It is noted that the number of channel layers 208 in the bottom portion 210B and the top portion 210T in the figures are for illustration purposes only. There can be more or less channel layers 208 in the bottom portion 210B, the top portion 210T, or both.

In one embodiment, the substrate 202 may be a silicon (Si) substrate. In some other embodiments, the substrate 202 may include other semiconductors such as germanium (Ge), silicon germanium (SiGe), or a III-V semiconductor material. Example III-V semiconductor materials may include gallium arsenide (GaAs), indium phosphide (InP), gallium phosphide (GaP), gallium nitride (GaN), gallium arsenide phosphide (GaAsP), aluminum indium arsenide (AlInAs), aluminum gallium arsenide (AlGaAs), gallium indium phosphide (GaInP), and indium gallium arsenide (InGaAs). The substrate 202 may also include an insulating layer, such as a silicon oxide layer, to have a silicon-on-insulator (SOI) structure. The channel layers 208 and the sacrificial layers 206 may have different semiconductor compositions. In some implementations, the channel layers 208 are formed of silicon (Si) and sacrificial layers 206 are formed of silicon germanium (SiGe). In these implementations, the additional germanium content in the sacrificial layers 206 allow selective removal or recess of the sacrificial layers 206 without substantial damages to the channel layers 208.

As shown in FIG. 2B, the workpiece 200 further includes an isolation feature 212 disposed around a base portion of the fin-shaped structure 210 to separate the fin-shaped structure 210 from an adjacent fin-shaped structure 210. The isolation feature 212 may also be referred to as a shallow trench isolation (STI) feature 212. In an example process, a dielectric material for the isolation feature is deposited over the workpiece 200, including the fin-shaped structure 210, using CVD, subatmospheric CVD (SACVD), flowable CVD (FCVD), spin-on coating, and/or other suitable process. Then the deposited dielectric material is planarized and recessed to form the isolation feature 212. The dielectric material for the isolation feature may include silicon oxide, silicon oxynitride, fluorine-doped silicate glass (FSG), a low-k dielectric, combinations thereof, and/or other suitable materials.

A block 102, dummy gate stacks 214 are formed over channel regions 210C of the fin-shaped structures 210. To form the dummy gate stack 214, a dummy dielectric layer 215, a dummy gate electrode layer 216, and a gate-top hard mask layer 216 are deposited over the workpiece 200. The deposition of these layers may include use of low-pressure CVD (LPCVD), CVD, plasma-enhanced CVD (PECVD), PVD, ALD, thermal oxidation, e-beam evaporation, or other suitable deposition techniques, or combinations thereof. The dummy dielectric layer 215 may include silicon oxide, the dummy gate electrode layer 216 may include polysilicon, and the gate-top hard mask layer 217 may be a multi-layer that includes silicon oxide and silicon nitride. Using photolithography and etching processes, the gate-top hard mask layer 217 is patterned. The photolithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. The etching process may include dry etching (e.g., RIE etching), wet etching, and/or other etching methods. Like the fin-shaped structures 210, the dummy gate stacks 214 may also be patterned using double-patterning or multiple-patterning techniques. Thereafter, using the patterned gate-top hard mask 217 as the etch mask, the dummy dielectric layer 215 and the dummy gate electrode layer 216 are then etched to form the dummy gate stacks 214. The dummy gate stacks 214 extend lengthwise along the Y direction to wrap over the fin-shaped structure 210 and lands on the isolation feature 212. The portion of the fin-shaped structure 210 underlying the dummy gate stacks 214 define the channel regions 210C. The channel regions 210C and the dummy gate stacks 214 also define source/drain regions 210SD that are not vertically overlapped by the dummy gate stacks 214. The channel region 210C is disposed between two source/drain regions 210SD along the X direction.

Referring to FIGS. 1, 2A and 2B, method 100 includes a block 104 where source/drain regions 210SD of the first fin-shaped structure 210 and the second fin-shaped structure 210 are recessed. It is noted that while FIG. 2A only shows one fin-shaped structure 210, FIG. 2B shows two fin-shaped structures 210 extending parallel to one another along the X direction. Operations at block 104 may include formation of the gate spacer 222 over the sidewalls of the dummy gate stack 214 before the source/drain regions 210SD are recessed. In some embodiments, the formation of the gate spacer 222 includes deposition of one or more dielectric layers over the workpiece 200, including the dummy gate stacks 214. In an example process, the one or more dielectric layers are conformally deposited using CVD, SACVD, or ALD. The one or more dielectric layers may include silicon oxide, silicon nitride, silicon carbide, silicon oxynitride, silicon carbonitride, silicon oxycarbide, silicon oxycarbonitride, and/or combinations thereof. After the deposition of the one or more dielectric layers, the workpiece 200 is etched in an anisotropic etch process to form the source/drain trenches 220. The etch process at block 104 may be a dry etch process or a suitable etch process. An example dry etch process may implement an oxygen-containing gas, hydrogen, a fluorine-containing gas (e.g., CF₄, SF₆, NF₃, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. After the source/drain trenches 220 are formed, sidewalls of the sacrificial layers 206 and the channel layers 208 in the channel regions 210C are exposed in the source/drain trenches 220. In the embodiments represented in FIGS. 2A and 2B, bottom surfaces of the source/drain trenches 220 terminate in the bottom silicon layer 208B.

The inner spacer features 224 and the middle dielectric layer 226 are formed after the formation of the source/drain trenches 220. To form the inner spacer features 224, the sacrificial layers 206 exposed in the source/drain trenches 220 are selectively and partially recessed to form inner spacer recesses, while the exposed channel layers 208 are substantially unetched. A middle sacrificial layer (not shown, replaced with the middle dielectric layer 226 in FIG. 2A), which includes a greater germanium content than the sacrificial layers 206, may be substantially removed during the formation of inner spacer recesses. After the formation of the inner spacer recesses, an inner spacer material layer is deposited over the workpiece 200, including in the inner spacer recesses. Additionally, as shown in FIG. 2A, the inner spacer material layer may also be deposited in the space left vacant by the removal of the middle sacrificial layer to form the middle dielectric layer 226. The inner spacer material layer may include silicon oxide, silicon nitride, silicon oxycarbide, silicon oxycarbonitride, silicon carbonitride, metal nitride, or a suitable dielectric material. The deposited inner spacer material layer is then etched back to remove excess inner spacer material layer over the gate spacer 222 and sidewalls of the channel layers 208, thereby forming the inner spacer features 224 and the middle dielectric layer 226 as shown in FIG. 2A.

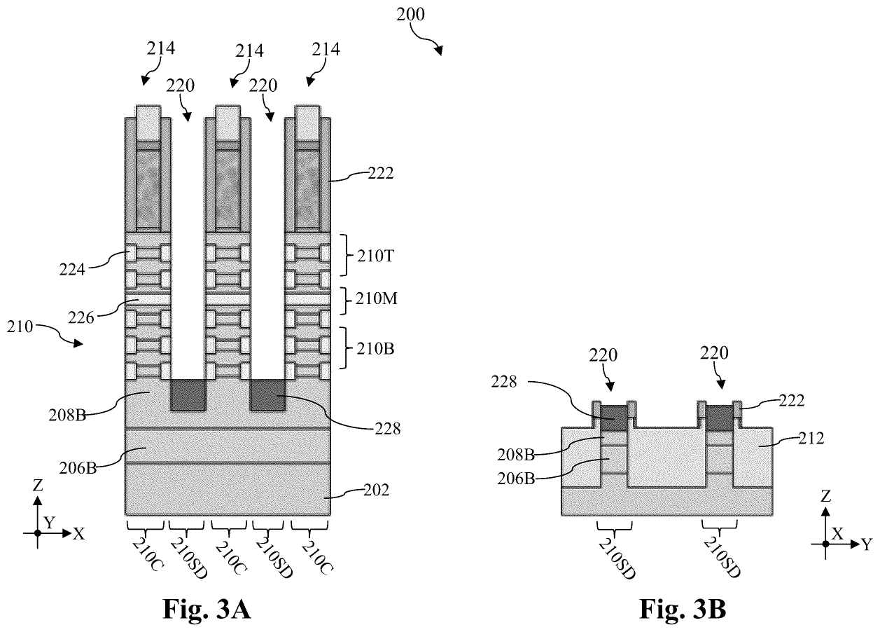

Referring to FIGS. 1, 3A and 3B, method 100 includes a block 106 where a leakage block layer 228 is formed over the source/drain regions 210SD. The leakage block layer 228 functions to reduce leakage into the substrate 202. The leakage block layer 228 may include undoped semiconductor material. In the depicted embodiments, the leakage block layer 228 includes undoped silicon (Si), undoped silicon germanium (SiGe), or undoped germanium (Ge). In these embodiments, the leakage block layer 228 may be deposited using vapor-phase epitaxy (VPE), ultra-high vacuum chemical vapor deposition (UHV-CVD), molecular beam epitaxy (MBE), and/or other suitable epitaxy deposition processes. As shown in FIG. 3B, a portion of the gate spacer 222 is disposed along sidewalls of the leakage block layer 228. In fact, a portion the leakage block layer 228 is sandwiched, along the Y direction, between two gate spacers 222.

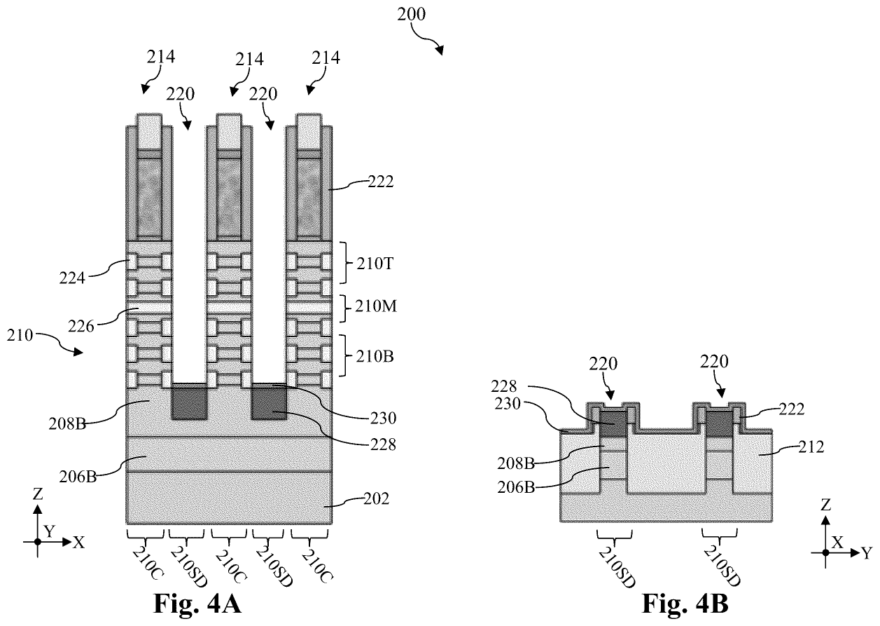

Referring to FIGS. 1, 4A and 4B, method 100 includes a block 110 where a sealing layer 230 is formed over the source/drain trenches 220. As shown in FIGS. 4A and 4B, at block 110, the sealing layer 230 is formed over and in contact with the isolation feature 212, the gate spacers 222, and the top surface of the leakage block layer 228. In some embodiments, the sealing layer 230 includes silicon nitride and may be conformally deposited over all exposed surfaces of the workpiece 200 using atomic layer deposition (ALD) or plasma-enhanced ALD (PE-ALD). After the conformal deposition, a bottom antireflective coating (BARC) layer or a silicon oxide layer may be deposited over the workpiece 200. The BARC layer or the silicon oxide layer is then etched back to cover only the sealing layer 230 on bottom surfaces of the source/drain trenches 220. An isotropic wet etch process, such as a phosphoric acid etch, is performed to remove the sealing layer 230 not covered by the BARC layer or the silicon oxide layer. After the isotropic wet etch process, the BARC layer or the silicon layer is selectively removed using ashing or selective etching. As shown in FIGS. 4A and 4B, after the operations at block 110, the sealing layer 230 remains deposited over top surfaces of the leakage block layer 228 over the source/drain regions 210SD. As shown in FIGS. 4A and 4B, the sealing layer 230 also covers the isolation feature 212 and the gate spacer 222 exposed in the source/drain trenches 220.

Referring to FIGS. 1, 4A and 4B, method 100 includes a block 112 where a first masking layer 232 is formed to cover a first region I. In some embodiments, the first masking layer 232 may be a photoresist layer and may be deposited using flowable CVD (FCVD). The first masking layer 232 may be a multilayer. In one embodiment, the first masking layer 232 is a tri-layer and includes a bottom layer, a middle layer disposed over the bottom layer, and a photosensitive layer over the middle layer. After the deposition of the first masking layer 232, a baking process may be performed to cure the first masking layer. After the curing of the first masking layer 232, the first masking layer 232 may be patterned using photolithography processes such that the first masking layer 232 covers the first region I while the second region II is not covered by the first masking layer 232. As shown in FIGS. 4A and 4B, the patterned first masking layer 232 covers the first region I, leaving the second region II uncovered.

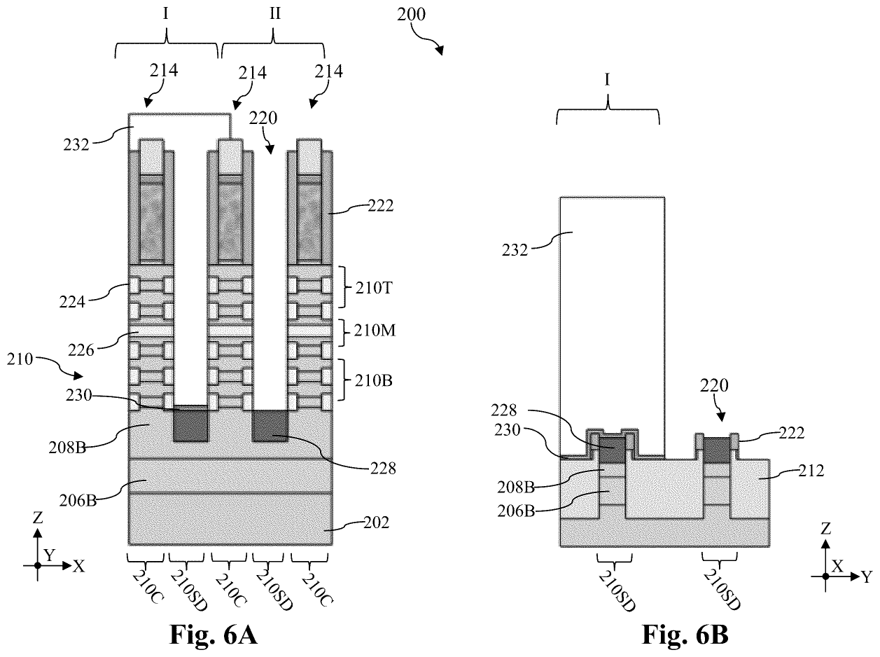

Referring to FIGS. 1, 6A, 6B, 7A, and 7B, method 100 includes a block 114 where the sealing layer 230 over a second region not covered by the first masking layer 232 is selectively removed. With the first masking layer 232 covering the first region I, a dry etch or a selective wet etch process is performed to remove the sealing layer 230 in the second region II. An example dry etch process may implement an oxygen-containing gas, hydrogen, a fluorine-containing gas (e.g., CF₄, SF₆, NF₃, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. An example wet etch process may include use of phosphoric acid. As shown in FIGS. 6A and 6B, the selective removal of the sealing layer 230 in the second region II leaves the leakage block layer 228 in the second region II exposed. After the selective removal of the sealing layer 230 in the second region II, the first masking layer 232 is removed by ashing or selective etching.

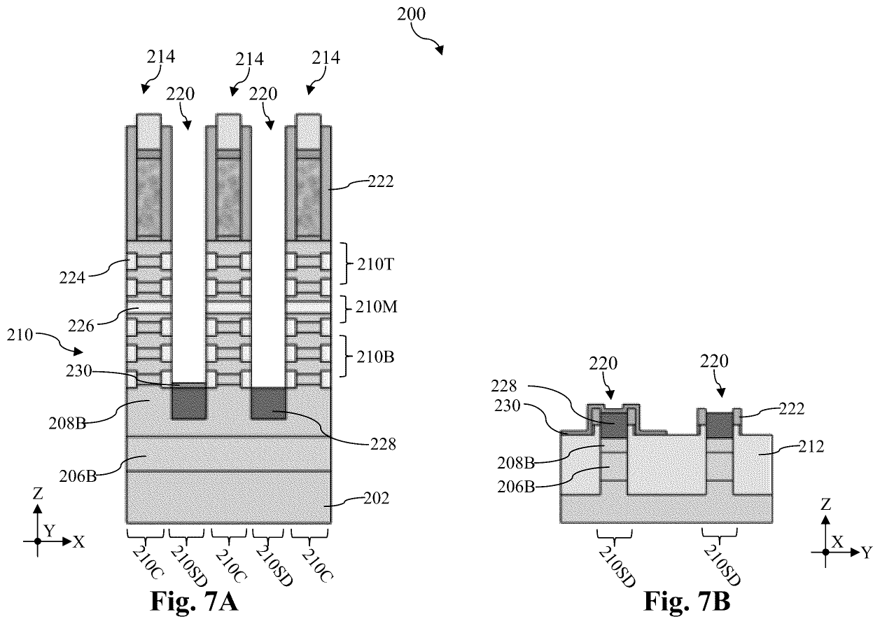

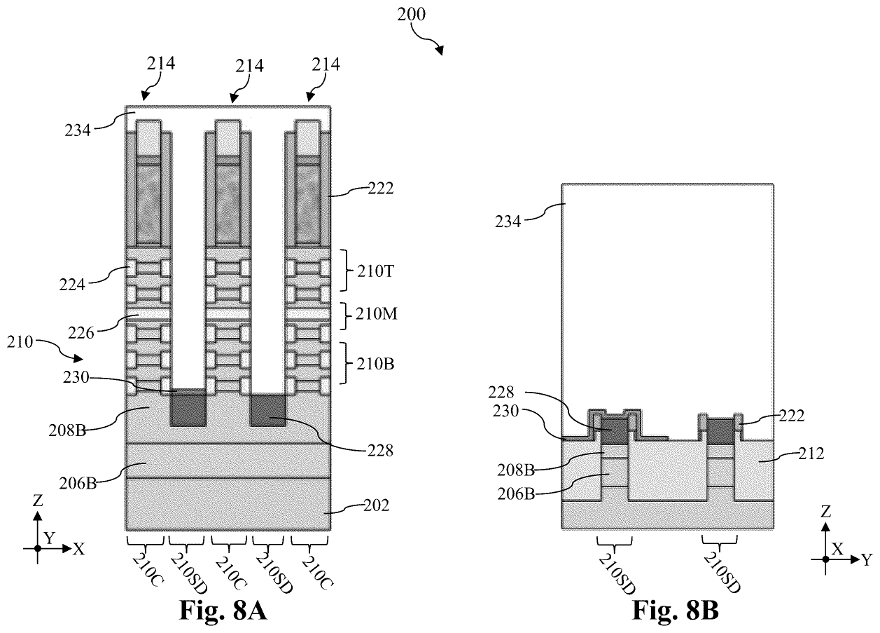

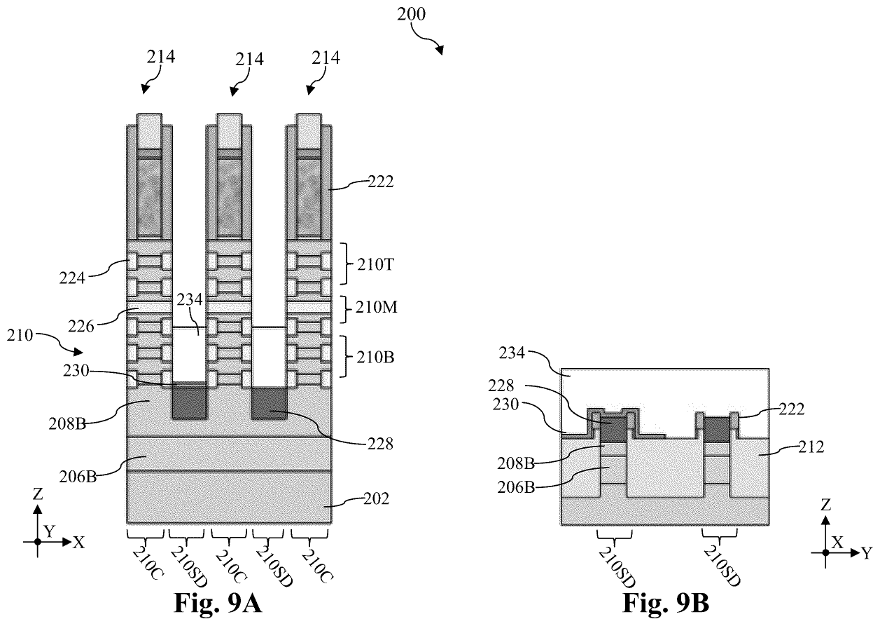

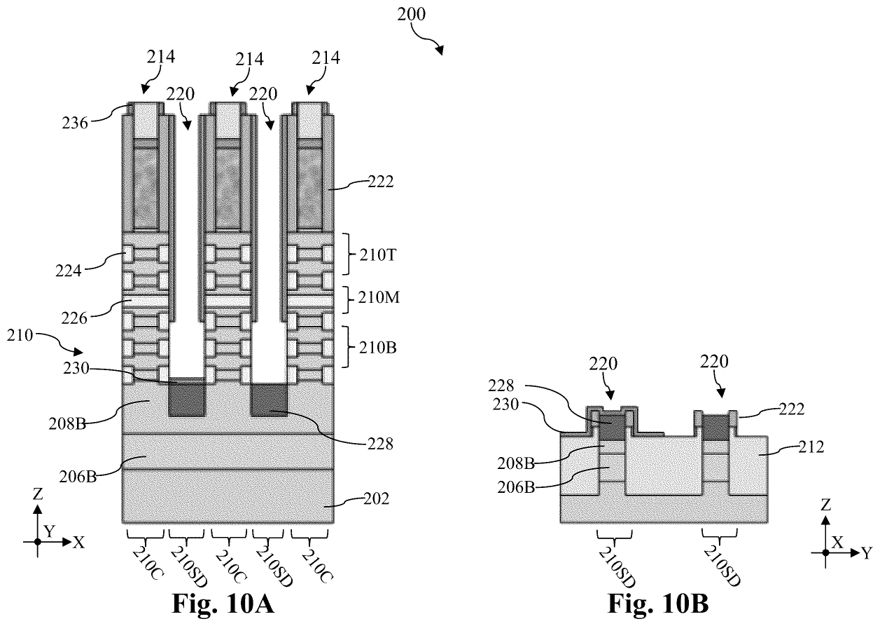

Referring to FIGS. 1, 8A-10A and 8B-10B, method 100 includes a block 116 where a dummy sidewall layer 236 is deposited over sidewalls of upper portions of the source/drain trenches 220. Operations at block 116 may include deposition of a dummy fill layer 234 over the workpiece 200 (shown in FIGS. 8A and 8B), etching back of the dummy fill layer 234 (shown in FIGS. 9A and 9B), conformal deposition of a dummy sidewall layer 236, an anisotropic etching of the dummy sidewall layer 236 to expose the dummy fill layer 234, and selective removal of the dummy fill layer 234 (shown in FIGS. 10A and 10B). Referring to FIGS. 8A and 8B, the dummy fill layer 234 is deposited over the workpiece 200, including over the source/drain trenches 220 shown in FIGS. 7A and 7B. In some embodiments, the dummy fill layer 234 includes silicon oxide and may be deposited using FCVD. In some embodiments, in order to improve the integrity of the dummy fill layer 234 to sustain etching back operations, an anneal may be performed after the deposition of the dummy fill layer 234.

Referring then to FIGS. 9A and 9B, the dummy fill layer 234 is etched back using an anisotropic dry etch process. In some embodiments, this dry etch process may include use of hydrogen (H₂), a fluorine-containing gas (e.g., CF₄, SF₆, NF₃, CH₂F₂, CHF₃, and/or C₂F₆), a chlorine-containing gas (e.g., Cl₂, CHCl₃, CCl₄, and/or BCl₃), or a bromine-containing gas (e.g., HBr and/or CHBr₃), an iodine-containing gas. As shown in FIG. 9A, the dry etch may be performed until the dummy fill layer 234 only covers sidewalls of the bottom portion 210B of the fin-shaped structure 210, leaving sidewalls of the middle portion 210M and top portion 210T exposed. In other words, the etching back of the dummy fill layer 234 is performed until a top surface of the dummy fill layer 234 is of a level around a boundary of the bottom portion 210B and the middle portion 210M.

Referring then to FIGS. 10A and 10B, the dummy fill layer 234 are selectively removed. To selectively remove the dummy fill layer 234, a dummy sidewall layer 236 is formed. In an example process, the dummy sidewall layer 236 is conformally deposited over the workpiece 200. The dummy sidewall layer 236 may include silicon nitride and may be deposited using ALD, PEALD, or CVD. It can be seen that the dummy fill layer 234 functions to prevent deposition of the dummy sidewall layer 236 on sidewalls of the bottom portion 210B. Then the dummy sidewall layer 236 is anisotropically etched back to remove the dummy sidewall layer 236 deposited on top-facing surfaces, thereby expose the dummy fill layer 234. In one embodiments, the etching back of the dummy sidewall layer 236 may be a dry etch process that uses oxygen (O₂), nitrogen (N₂), a fluorine-containing gas (e.g., CF₄, SF₆, NF₃, CH₂F₂, CHF₃, and/or C₂F₆), a chlorine-containing gas (e.g., Cl₂, CHCl₃, CCl₄, and/or BCl₃), or a bromine-containing gas (e.g., HBr and/or CHBr₃), an iodine-containing gas. The etching back patterns the dummy sidewall layer 236 to form the dummy sidewall layer 236. It is noted that the same reference numeral is used to refer to the dummy sidewall layer 236 as well as the dummy sidewall layer 236 leading to the formation of the dummy sidewall layer 236. In an embodiment where the dummy fill layer 234 includes silicon oxide and the dummy sidewall layer 236 includes silicon nitride, the selective removal of the dummy fill layer 234 may be achieved with a wet etch process that uses hydrofluoric acid (HF) or a buffered hydrofluoric acid solution (BHF). As shown in FIGS. 10A and 10B, after the removal of the dummy fill layer 234, the dummy sidewall layer 236 is formed to cover sidewalls of the middle portion 210M and the top portion 210T.

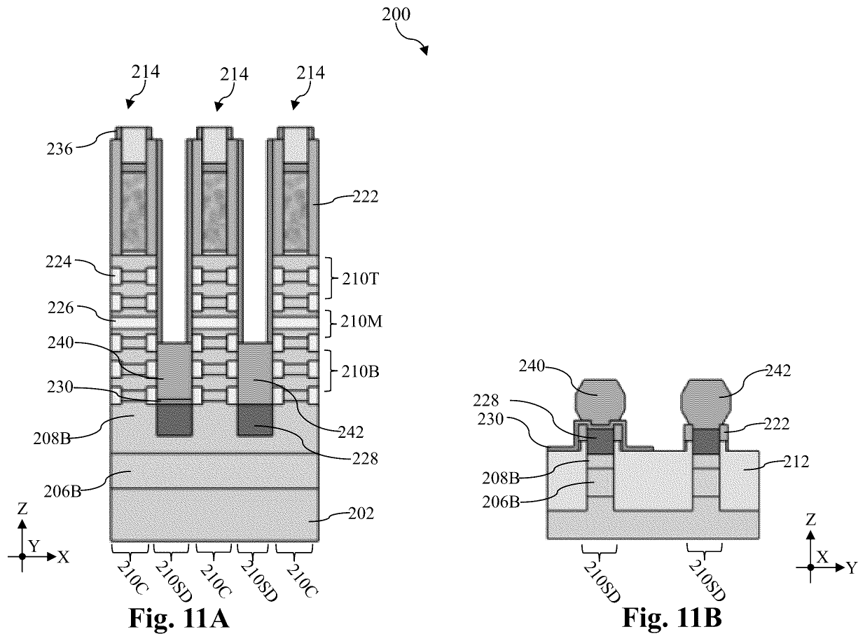

Referring to FIGS. 1, 11A-12A and 11B-12B, method 100 includes a block 118 where bottom source/drain features 240 and 242 are formed over the source/drain regions 210SD. The bottom source/drain features 240 and 242 may be formed using an epitaxial process, such as VPE, UHV-CVD, MBE, and/or other suitable processes. The epitaxial growth process may use gaseous and/or liquid precursors, which interact with the composition of the leakage block layer 228 as well as the channel layers 208. The epitaxial growth of the bottom source/drain feature 242 may take place from both the top surface of the leakage block layer 228 and the exposed sidewalls of the bottom channel layers 208. The epitaxial growth of the bottom source/drain feature 240 may take place only from the exposed sidewalls of the bottom channel layers 208. The dummy sidewall layer 236, due to its dielectric composition, blocks formation of the bottom source/drain feature on sidewalls of the channel layers 208 in the middle portion 210M and the top portion 210T. As illustrated in FIG. 11A, the deposited bottom source/drain features 240 and 242 are in physical contact with (or adjoining) the channel layers 208 in the bottom portion 210B. Although the epitaxial growth of bottom source/drain features 240 and 242 is less likely to take place on surfaces of the inner spacer features 224, overgrowth of the bottom source/drain features 240 and 242 allow the bottom source/drain features 240 and 242 to merge over the inner spacer features 224. In the embodiments represented in the figures, the bottom source/drain features 240 and 242 are p-type and silicon germanium (SiGe) doped with a p-type dopant, such as boron (B) In these depicted embodiments, the bottom source/drain features 240 and 242 may include boron doped silicon germanium (SiGe:B).

The bottom source/drain feature 240 and the bottom source/drain 242 are different in terms of the environment in which they are formed. The bottom source/drain feature 242 is formed not only on the sidewalls of the channel layers 208 in the bottom portion 210B but also on a semiconductor surface of the leakage block layer 228. As a result, the bottom source/drain feature 242 has less defect and is able to exert more strain on the channel layers 208. Due to nature of the epitaxial growth that forms the bottom source/drain feature 240, the bottom source/drain feature 240 is not grown from the top surface of the sealing layer 230, which is formed of a dielectric material. The bottom source/drain feature 240 is therefore only formed on the sidewalls of the channel layers 208, unaided by the semiconductor surface of the leakage block layer 228. As a result, the bottom source/drain feature 242 has more defect and exerts little or no strain on the channel layers 208. For ease of reference, the bottom source/drain feature 242 on the leakage block layer 228 may also be referred to as a high-strain bottom source/drain feature 242 and the bottom source/drain feature 240 on the sealing layer 230 may be referred to a low-strain bottom source/drain feature 240.

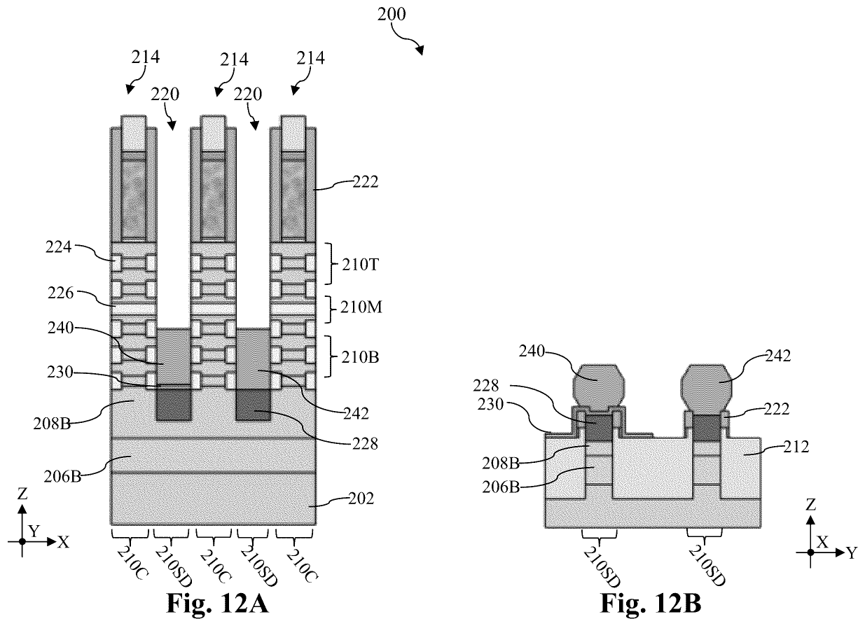

Reference is now made to FIGS. 12A and 12B. After the formation of the high-strain bottom source/drain feature 242 and the low-strain bottom source/drain feature 240, the dummy sidewall layer 236 is selectively removed by a selective etch process, such as a wet etch process that uses hot phosphoric acid.

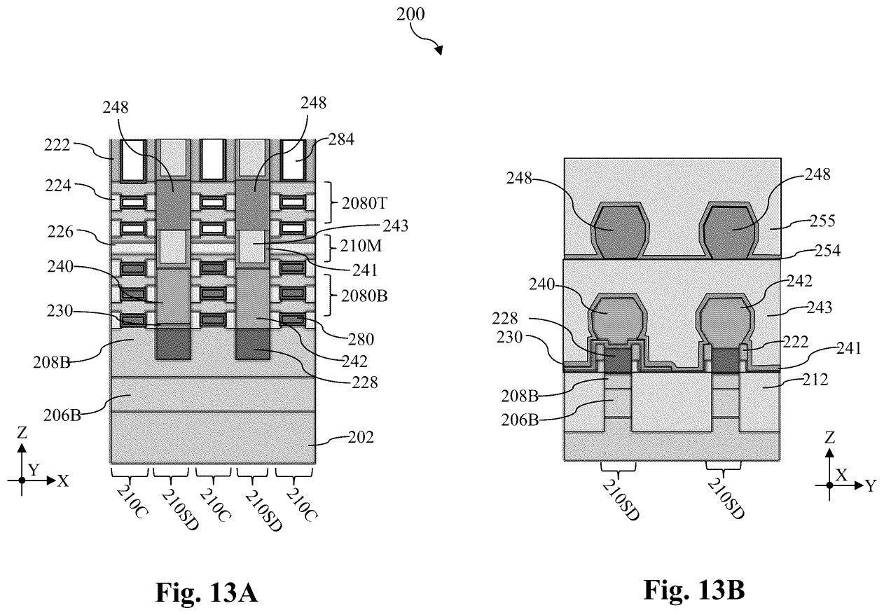

Referring to FIGS. 1, 13A and 13B, method 100 includes a block 120 where a bottom contact etch stop layer (CESL) 241 and a bottom interlayer dielectric (ILD) layer 243 are deposited. The bottom CESL 241 may include silicon nitride, silicon oxynitride, and/or other materials known in the art. The bottom ILD layer 243 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. and may be formed by CVD, ALD, plasma-enhanced chemical vapor deposition (PECVD) process and/or other suitable deposition or oxidation processes. In some embodiments, the bottom CESL 241 is first conformally deposited on the workpiece 200 using CVD, ALD, PECVD and the bottom ILD layer 243 is deposited over the bottom CESL 241 by spin-on coating, FCVD, CVD, or other suitable deposition technique. In some embodiments, after formation of the bottom ILD layer 243, the workpiece 200 may be annealed to improve integrity of the bottom ILD layer 243. As shown in FIG. 13A, after the deposition of the bottom CESL 241 and the bottom ILD layer 243, the bottom CESL 241 and the bottom ILD layer 243 are etched back to exposed sidewalls of the channel layers 208 in the top portion 210T.

Referring to FIGS. 1, 13A and 13B, method 100 includes a block 122 where top source/drain features 248 are formed. The top source/drain features 248 may be formed using an epitaxial process, such as VPE, UHV-CVD, MBE, and/or other suitable processes. The epitaxial growth process may use gaseous and/or liquid precursors, which interact with composition of the channel layers 208 formed in the top portion 210T. It is noted that the channel layers 208 in the top portion 210T (shown in FIG. 12A) are already released as top channel members 2080T in FIG. 13A. The epitaxial growth of top source/drain features 248 may take place from the exposed sidewalls of the channel layers 208 in the top portion 210T. The deposited top source/drain features 248 are in physical contact with (or adjoining) the channel layers 208 in the top portion 210T. It is noted that because the epitaxial growth is less likely to take place on surfaces of the bottom CESL 241 or the bottom ILD layer 243. In the depicted embodiments, the top source/drain features 248 are n-type source/drain features and may include silicon (Si) doped with an n-type dopant, such as phosphorus (P). In these depicted embodiments, the top source/drain features 248 may include phosphorus doped silicon (Si:P).

Referring to FIGS. 1, 13A and 13B, method 100 includes a block 124 where further processes are performed. Such further processes performed at block 124 may include deposition of a top CESL 254 and a top ILD layer 255 over the top source/drain features 248, release of the channel layers 208 as bottom channel members 2080B and top channel members 2080T, removal of the dummy gate stacks 214, and formation of a bottom gate structure 280 and a top gate structure 284. The top CESL 254 and a top ILD layer 255 are deposited over the top source/drain features 248. The composition and the deposition process of the top CESL 254 are similar to those of the bottom CESL 241. The composition and the deposition process of the top ILD layer 255 are similar to those of the bottom ILD layer 243. Accordingly, detailed description of the top CESL 254 and the top ILD layer 255 is omitted for brevity. To remove excess materials and to expose top surfaces of the dummy gate stacks 214, a planarization process, such a chemical mechanical polishing (CMP) process may be performed.

The removal of the dummy gate stacks 214 may include one or more etching processes that are selective to the material in the dummy gate stacks 214. For example, the removal of the dummy gate stacks 214 may be performed using as a selective wet etch, a selective dry etch, or a combination thereof. After the removal of the dummy gate stacks 214, sidewalls of the channel layers 208 and sacrificial layers 206 in the top portion 210T and the bottom portion 210B are exposed. Thereafter, the sacrificial layers 206 in the top portion 210T and the bottom portion 210B are selectively removed to release the channel layers 208 as top channel members 2080T and bottom channel members 2080B. The bottom channel members 2080B are situated below the middle dielectric layer 226M and top channel members 2080T are above the middle dielectric layer 226M. Here, because the dimensions of the top channel members 2080T and bottom channel members 2080B are nanoscale, they may also be referred to as nanostructures. The selective removal of the sacrificial layers 206 may be implemented by selective dry etch, selective wet etch, or other selective etch processes. In some embodiments, the selective wet etching includes an APM etch (e.g., ammonia hydroxide-hydrogen peroxide-water mixture). In some other embodiments, the selective removal includes SiGe oxidation followed by a silicon germanium oxide removal. For example, the oxidation may be provided by ozone clean and then silicon germanium oxide removed by an etchant such as NH₄OH.

With the bottom channel members 2080B and top channel members 2080T released, a bottom gate structure 280 is deposited to wrap around each of the bottom channel members 2080B and a top gate structure 284 is deposited to wrap around each of the top channel members 2080T. The bottom gate structure 280 turns on the bottom channel members 2080B and forms a bottom multi-gate transistor. The top gate structure 284 turns on the top channel members 2080T to form a top multi-gate transistor. In the embodiments represented in FIGS. 13A and 13B, the bottom multi-gate transistor is a p-type device and the top multi-gate transistor is an n-type device. While not explicitly shown in the figures, each of the bottom gate structure 280 and the top gate structure 284 includes an interfacial layer to interface the bottom channel members 2080B or top channel members 2080T and a gate dielectric layer over the interfacial layer. The bottom gate structure 280 includes a p-type work function layer. The top gate structure 284 includes an n-type work function layer. In some embodiments, the interfacial layer includes silicon oxide and may be formed in a pre-clean process. An example pre-clean process may include use of RCA SC-1 (ammonia, hydrogen peroxide and water) and/or RCA SC-2 (hydrochloric acid, hydrogen peroxide and water). The gate dielectric layer is then deposited over the interfacial layer using ALD, CVD, and/or other suitable methods. The gate dielectric layer is formed of high-K dielectric materials. As used and described herein, high-k dielectric materials include dielectric materials having a high dielectric constant, for example, greater than that of thermal silicon oxide (˜3.9). The gate dielectric layer may include hafnium oxide. Alternatively, the gate dielectric layer may include other high-K dielectrics, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), SrTiO₃ (STO), BaTiO₃ (BTO), BaZrO, hafnium lanthanum oxide (HfLaO), lanthanum silicon oxide (LaSiO), aluminum silicon oxide (AlSiO), hafnium tantalum oxide (HfTaO), hafnium titanium oxide (HfTiO), (Ba,Sr)TiO₃ (BST), silicon nitride (SiN), silicon oxynitride (SiON), combinations thereof, or other suitable material.

After the deposition of the gate dielectric layer, at least one p-type work function layer may be deposited to form the bottom gate structure 280 and at least one n-type work function layer may be deposited to form the top gate structure 284. Each of the bottom gate structure 280 and the top gate structure 284 may also include a liner layer, a wetting layer, an adhesion layer, a metal alloy or a metal silicide. By way of example, the at least one p-type work function layer may include titanium nitride (TiN), tantalum nitride (TaN), ruthenium (Ru), molybdenum (Mo), aluminum (Al), tungsten nitride (WN), zirconium silicide (ZrSi₂), molybdenum silicide (MoSi₂), tantalum silicide (TaSi₂), nickel silicide (NiSi₂), other p-type work function material, or combinations thereof. The at least one n-type work function layer may include titanium (Ti), aluminum (Al), silver (Ag), manganese (Mn), zirconium (Zr), titanium aluminum (TiAl), titanium aluminum carbide (TiAlC), tantalum carbide (TaC), tantalum carbonitride (TaCN), tantalum silicide nitride (TaSiN), tantalum aluminum (TaAl), tantalum aluminum carbide (TaAlC), titanium aluminum nitride (TiAlN), other n-type work function material, or combinations thereof. In some instances, the top gate structure 284 may also include a metal fill to reduce contact resistance. In some instance, the metal fill includes tungsten (W). As shown in FIG. 13A, the bottom gate structure 280 wraps around each of the bottom channel members 2080B and the top gate structure 284 wraps around each of the top channel members 2080T. In the embodiments represented in FIG. 13A, the two channel layers 208 in the middle portion 210M are not released as the bottom channel members 2080B or the top channel members 2080T. They remain in contact with the middle dielectric layer 226. Further, the two channel layers 208 are end-capped by the bottom CESL 241 along the X direction.

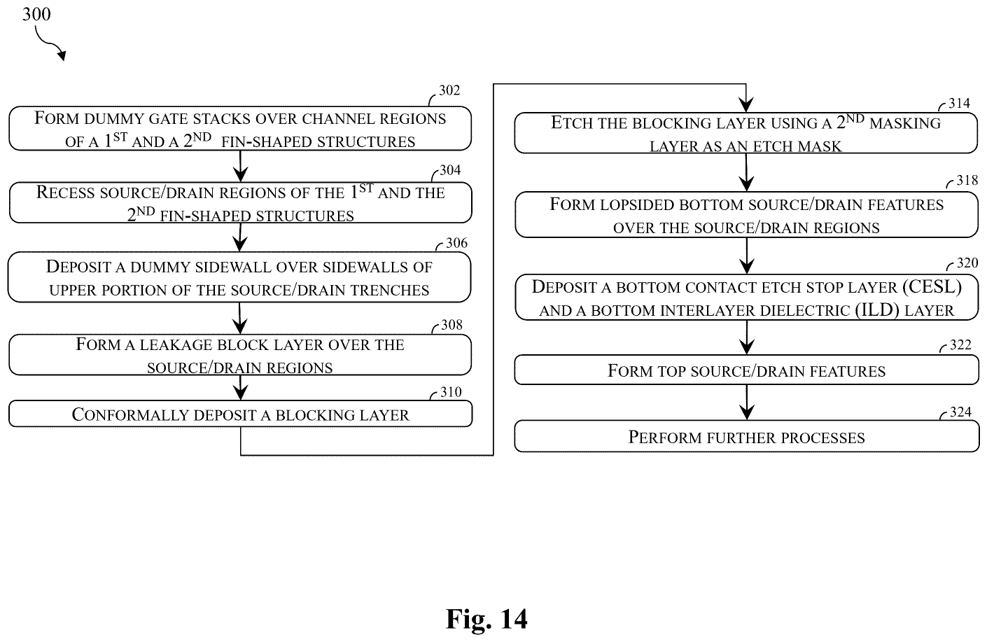

Method 300 in FIG. 14 forms a C-FET where volumes of source/drain features of bottom multi-gate devices are reduced.

Referring to FIGS. 14, 15A and 15B, method 300 includes a block 302 where dummy gate stacks 214 are formed over channel regions 210C of a first fin-shaped structure 210 and a second fin-shaped structure 210. Operations at block 302 are similar to those described above with respect to block 102. Detailed description of operations at block 302 is omitted for brevity.

Referring to FIGS. 14, 15A and 15B, method 300 includes a block 304 where source/drain regions 210SD of the first fin-shaped structure 210 and the second fin-shaped structure 210 are recessed. It is noted that while FIG. 15A only shows one fin-shaped structure 210, FIG. 15B shows two fin-shaped structures 210 extending parallel to one another along the X direction. Operations at block 304 are similar to those described above with respect to block 104. Detailed description of operations at block 304 is omitted for brevity.

Referring to FIGS. 14, 15A and 15B, method 300 includes a block 306 where a dummy sidewall layer 236 is deposited over sidewalls of upper portions of the source/drain trenches 220. Operations at block 306 are similar to those described above with respect to block 116, with the exception that the dummy sidewall layer 236 in method 300 is formed before the deposition of the leakage block layer 228 and method 300 does not include any counterpart for the formation of the sealing layer 230. Detailed description of operations at block 306 is omitted for brevity.

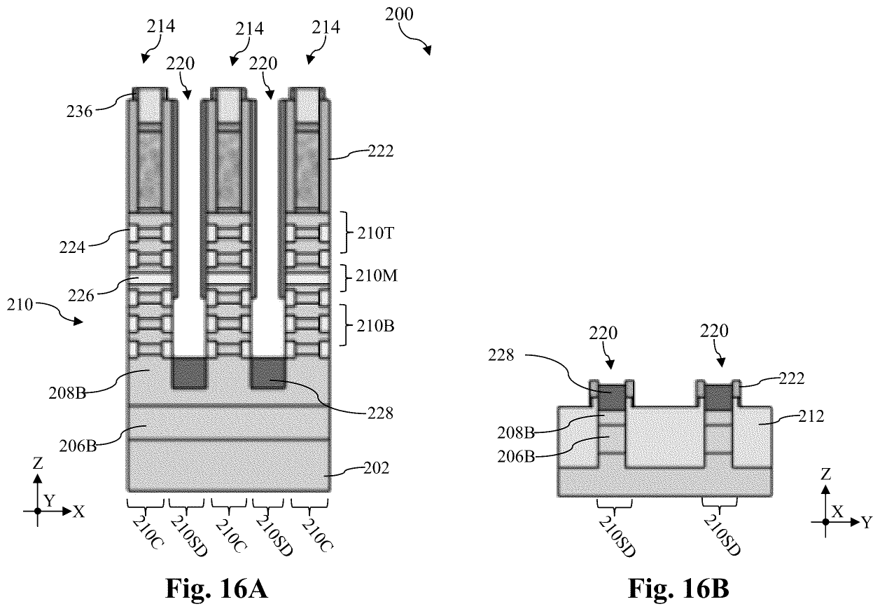

Referring to FIGS. 14, 16A and 16B, method 300 includes a block 308 where a leakage block layer 228 is formed over the source/drain regions 210SD. Operations at block 308 are similar to those described above with respect to block 106. Detailed description of operations at block 308 is omitted for brevity. It is noted that, different from method 100, method 300 forms the leakage block layer 228 in the source/drain trenches 220 after the formation of the dummy sidewall layer 236.

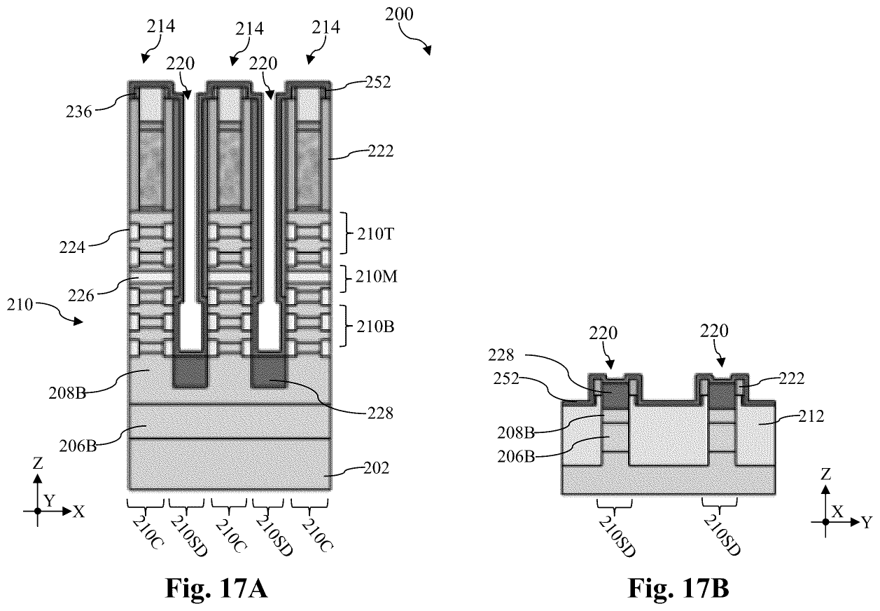

Referring to FIGS. 14, 17A and 17B, method 300 includes a block 310 where a blocking layer 252 is formed over the workpiece 200. The blocking layer 252 includes metal oxide. In some embodiments, the blocking layer 252 includes aluminum oxide and may be conformally deposited over the workpiece 200 using ALD. As shown in FIGS. 17A and 17B, the blocking layer 252 conformally extends along and is in contact with the dummy sidewall layer 236, sidewalls of the channel layers 208 in the bottom portion 210B, top surfaces of the leakage blocking layer 228, and top surfaces of the gate-top hard mask layer 217. Referring to FIG. 17B, the blocking layer 252 is in contact with the isolation feature 212, the gate spacer 222 adjacent the leakage blocking layer 228.

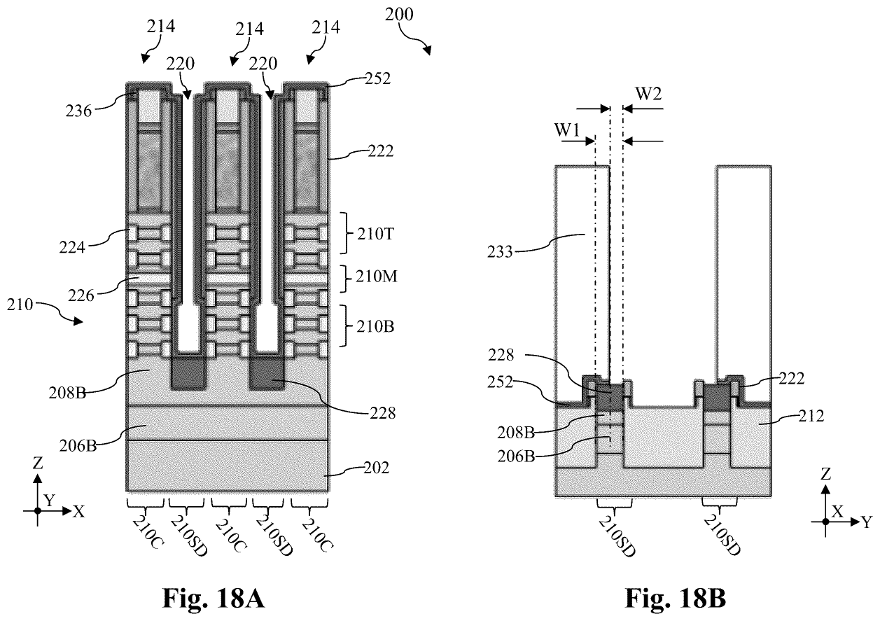

Referring to FIGS. 14, 18A and 18B, method 300 includes a block 314 where the blocking layer 252 is etched using a second masking layer 233 as an etch mask. In an example process, the second masking layer 233 may be a photoresist layer and may be deposited using flowable CVD (FCVD). The first masking layer 232 may be a multilayer. In one embodiment, the second masking layer 233 is a tri-layer and includes a bottom layer, a middle layer disposed over the bottom layer, and a photosensitive layer over the middle layer. After the deposition of the second masking layer 233, a baking process may be performed to cure the second masking layer 233. After the curing of the second masking layer 233, the second masking layer 233 may be patterned using photolithography processes such that the second masking layer 233 covers one half of the top surfaces of the leakage blocking layer 228. As shown in FIG. 18B, when viewed along a lengthwise direction of the fin-shaped structures 210 (i.e., the X direction, the second masking layer 233 covers one half of the width of the leakage blocking layer 228 along the Y direction. With the second masking layer 233 in place, the blocking layer 252 is etched using a dry etch process, such as one that uses a chlorine-containing gas (e.g., Cl₂, CHCl₃, CCl₄, and/or BCl₃). In some alternative embodiments, the blocking layer 252 that is not covered by the second masking layer 233 may be etched using a wet etch process that uses hydrofluoric acid. As shown in FIG. 18B, once the portion of the blocking layer 252 not covered by the second masking layer 233 is removed, one half of the top surfaces of the leakage blocking layer 228 are exposed to serve as semiconductor surfaces conducive to epitaxial growth. After the blocking layer 252 is patterned, the second masking layer 233 is removed by ashing or selective etching.

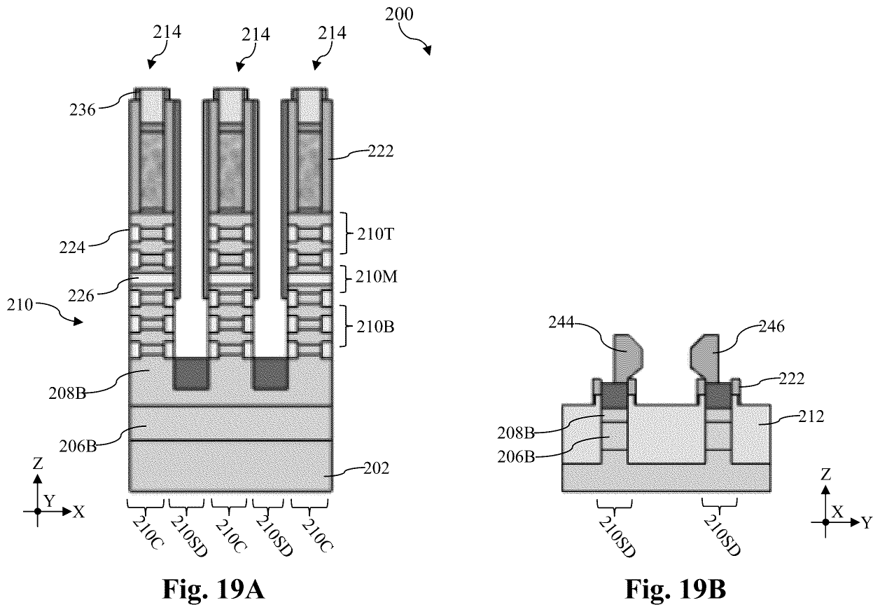

Referring to FIGS. 17, 19A and 19B, method 300 includes a block 318 where lopsided bottom source/drain features 244 and 246 are formed over the source/drain regions 210SD. The lopsided bottom source/drain features 244 and 246 may be formed using an epitaxial process, such as VPE, UHV-CVD, MBE, and/or other suitable processes. The epitaxial growth process may use gaseous and/or liquid precursors, which interact with the composition of the exposed portions of the leakage block layer 228 as well as the channel layers 208. The epitaxial growth of the lopsided bottom source/drain features 244 and 246 may take place from both the top surface of the leakage block layer 228 and the exposed sidewalls of the bottom channel layers 208. The blocking layer 252, due to its dielectric composition, blocks formation of the lopsided bottom source/drain features 244 and 246 from a portion of the leakage blocking layer 228. The presence of the blocking layer 252 (shown in FIG. 19B) gives the lopsided shapes of the lopsided bottom source/drain features 244 and 246. Referring to FIGS. 19B, the lopsided bottom source/drain feature 244 is offset toward the right-hand side while the lopsided bottom source/drain feature 246 is offset toward the left-hand side. The lopsided bottom source/drain features 244 and 246 are not visible in FIG. 19A because the fragmentary cross-sectional view in FIG. 19A only passes through the dummy sidewall layer 236. Although the epitaxial growth of the lopsided bottom source/drain features 244 and 246 is less likely to take place on surfaces of the inner spacer features 224, overgrowth of the lopsided bottom source/drain features 244 and 246 allow the lopsided bottom source/drain features 244 and 246 to merge over the inner spacer features 224. In the embodiments represented in the figures, the lopsided bottom source/drain features 244 and 246 are p-type and silicon germanium (SiGe) doped with a p-type dopant, such as boron (B) In these depicted embodiments, the lopsided bottom source/drain features 244 and 246 may include boron doped silicon germanium (SiGe:B). After the formation of the lopsided bottom source/drain features 244 and 246, the blocking layer 252 is removed by a dry etch process or a wet etch process. In one embodiment, the blocking layer 252 is removed by a dry etch process that uses a chlorine-containing gas (e.g., Cl₂, CHCl₃, CCl₄, and/or BCl₃). In another embodiment, the blocking layer 252 is removed by a wet etch process that uses hydrofluoric acid.

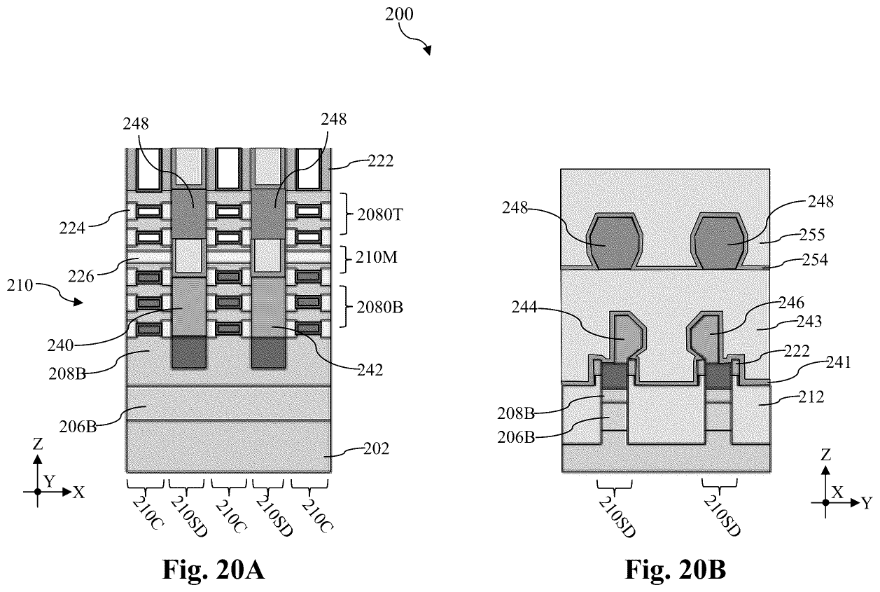

Referring to FIGS. 14, 20A and 20B, method 100 includes a block 320 where a bottom contact etch stop layer (CESL) 241 and a bottom interlayer dielectric (ILD) layer 243 are deposited. Operations at block 320 are similar to those described above with respect to block 120. Detailed description of operations at block 302 is omitted for brevity. As shown in FIG. 20B, because the removed blocking layer 252 exposes one half of the top surfaces of the leakage blocking layer 228, the bottom CESL 241 may come in direct contact with the leakage blocking layer 228. Each of the lopsided bottom source/drain features 244 and 246 includes a vertical sidewall that rises from the top surfaces of the leakage blocking layer 228. The bottom CESL 241 is disposed along and in contact with the vertical sidewalls of the lopsided bottom source/drain features 244 and 246.

Referring to FIGS. 14, 20A and 20B, method 300 includes a block 322 where top source/drain features 248 are formed. Operations at block 322 are similar to those described above with respect to block 122. Detailed description of operations at block 322 is omitted for brevity.

Referring to FIGS. 14, 20A and 20B, method 300 includes a block 324 where further processes are performed. Operations at block 324 are similar to those described above with respect to block 124. Detailed description of operations at block 324 is omitted for brevity.

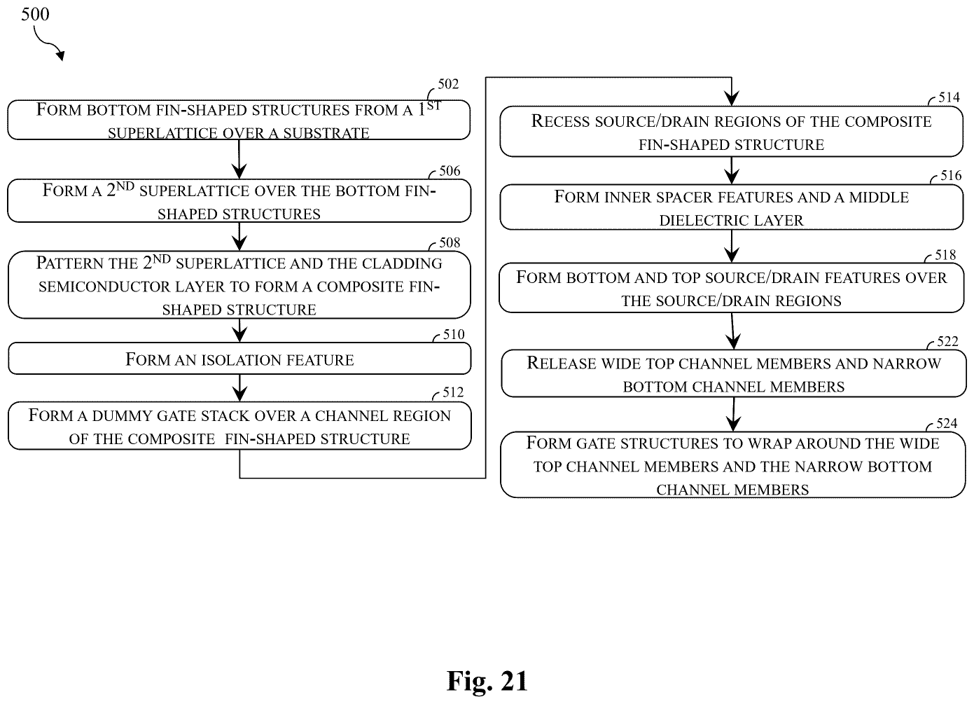

Method 500 in FIG. 21 forms a C-FET using a partially sequential process where bottom multi-gate devices have smaller channel widths than top multi-gate devices.

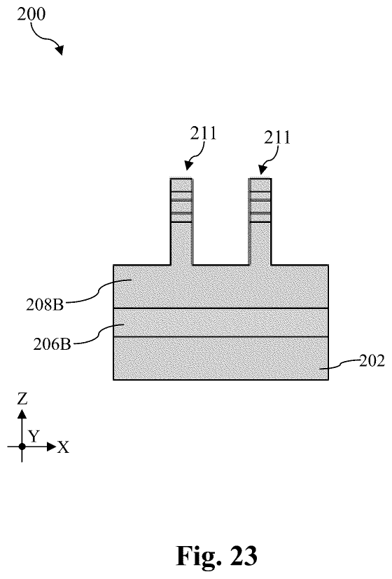

Referring to FIGS. 21, 22 and 23, method 500 includes a block 502 where a bottom fin-shape structures 211 are formed from a first superlattice 204B over a substrate 202. Referring to FIG. 22, a first superlattice 204B is deposited over a substrate 202. As similarly described above with respect to block 102 of method 100, the workpiece 200 may further include a bottom silicon germanium layer 206B disposed on the substrate 202, and a bottom silicon layer 208B disposed on the bottom silicon germanium layer 206B. In the illustrated embodiments, the first superlattice 204B includes two channel layers 208 interleaved by two sacrificial layers 206, with one of the sacrificial layers 206 disposed directly on the bottom silicon layer 208B. The compositions of the channel layers 208 and sacrificial layers 206 have been described above and detailed description thereof is omitted for brevity. Referring to FIG. 23, bottom fin-shaped structures 211 are formed from the first superlattice 204B and a portion of the bottom silicon layer 208B. The formation of the bottom fin-shaped structures 211 is similar to the formation of the fin-shaped structures 210 described above. Detailed description of the formation of the bottom fin-shaped structures 211 is therefore omitted.

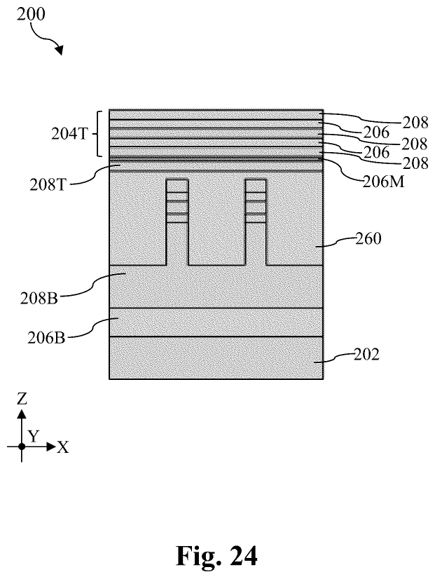

Referring to FIGS. 21 and 24, method 500 includes a block 506 where a second superlattice 204T is formed over the bottom fin-shaped structures 211. In an example process, a cladding semiconductor layer 260 is deposited over the bottom fin-shaped structures 211. In some embodiments, the cladding semiconductor layer 260 includes silicon germanium (SiGe) and may be deposited using VPE, UHV-CVD, or MBE. In some embodiments, a composition or germanium content of the cladding semiconductor layer 260 may be the same as the sacrificial layers 206. In some implementations, a planarization process, such as a chemical mechanical polishing (CMP) process, may be performed to the workpiece 200 to provide a planar top surface that includes the cladding semiconductor layer 260. Using epitaxial growth processes such as VPE, UHV-CVD, or MBE, a top silicon layer 208T, a middle sacrificial layer 206M, and the second superlattice 204T are deposited over the cladding semiconductor layer 260 layer-by-layer. The top silicon layer 208T includes silicon (Si). The middle sacrificial layer 206M includes silicon germanium. Compared to the sacrificial layers 206, the middle sacrificial layer 206M may include additional germanium content to allow it to be selectively removed. The second superlattice 204T shown in FIG. 24 includes a plurality of channel layers 208 interleaved by a plurality of sacrificial layers 206. It is noted that the second superlattice 204T one more channel layer 208 than the first superlattice 204B because the middle sacrificial layer 206M has to be sandwiched between two silicon layers. Other arrangements are possible.

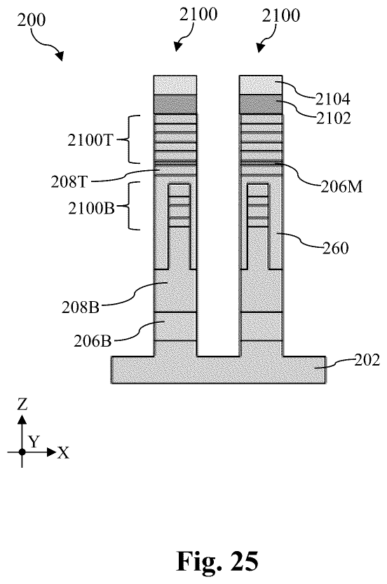

Referring to FIGS. 21 and 25, method 500 includes a block 508 where a second superlattice 204T, the cladding semiconductor layer 260, and the bottom fin-shaped structure 211 are patterned to form composite fin-shaped structures 2100. The formation process of the composite fin-shaped structures 2100 is similar to the process used to pattern the fin-shaped structure 210 described above. In one embodiment, a first hard mask 2102 and a second hard mask 2104 are deposited over the workpiece 200 and patterned using photolithography processes. In some embodiments, the first hard mask 2102 may include silicon nitride and the second hard mask 2104 may include silicon oxide. The patterned first hard mask 2102 and second hard mask 2104 are then applied as an etch mask to pattern the substrate 202, the bottom silicon germanium layer 206B, the bottom silicon layer 208B, the cladding semiconductor layer 260, the top silicon layer 208T, the middle sacrificial layer 206M, and second superlattice 204T, in order to form the composite fin-shaped structures 2100. Each of the composite fin-shaped structures 2100 includes, among other layers, a bottom portion 2100B and a top portion 2100T. The bottom portion 2100B includes the channel layers 208 and sacrificial layers 206 in the first superlattice 204B. The top portion 2100T includes the channel layers 208 and sacrificial layers 206 in the second superlattice 204T.

As shown in FIG. 25, a width of the composite fin-shaped structures 2100 along the X direction is greater than a width of the bottom fin-shaped structures 211. The difference in width is made up by the cladding semiconductor layer 260. The difference in width not only affects the channel width but also matters in terms of process robustness. It can be seen that as long as the top portion 2100T is wide enough to completely overlap the bottom portion 2100B, it does not matter whether the bottom portion 2100B is centered with the top portion 2100T.

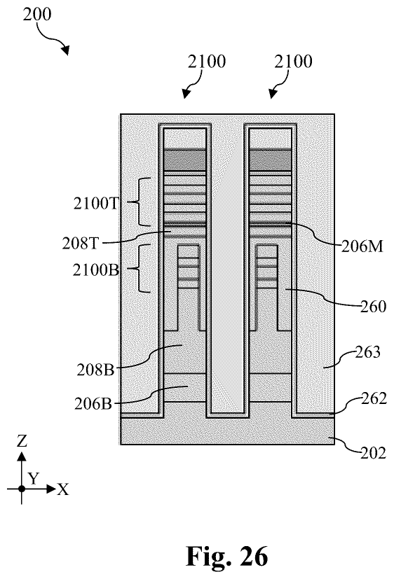

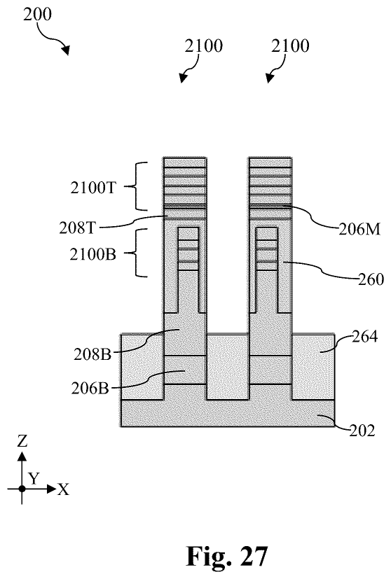

Referring to FIGS. 21, 26 and 27, method 500 includes a block 510 where an isolation feature 264 is formed around the composite fin-shaped structures 2100. Reference is first made to FIG. 26. In some embodiments, a liner 262 is first conformally deposited over the workpiece 200, including the surfaces of the composite fin-shaped structures 2100 and the trenches between the composite fin-shaped structures 2100. In some implementations, the liner 262 includes silicon oxide and may be deposited using ALD. A dielectric material 263 is then deposited over the liner 262 using FCVD. It is noted that the liner 262 and the dielectric material 263 are deposited using different deposition methods. Referring to FIG. 27, the liner 262 and the dielectric material 263 are then etched back to form the isolation feature 264, which is in contact with the substrate 202, the bottom silicon germanium layer 206B, and a lower portion of the bottom silicon layer 208B.

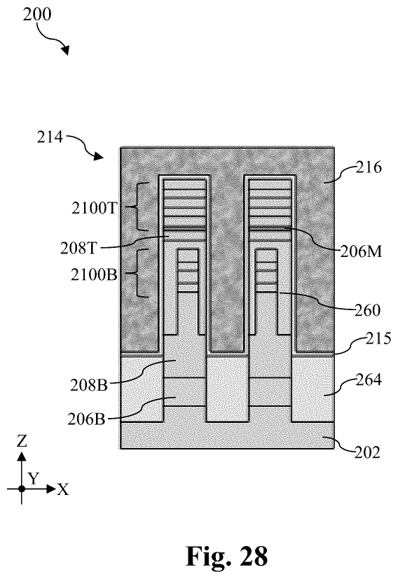

Referring to FIGS. 21 and 28, method 500 includes a block 512 where a dummy gate stack 214 is formed over channel regions of the composite fin-shaped structures 2100. Operations at block 512 are similar to those described above with respect to block 102. Detailed description of operations at block 512 is omitted for brevity.

Referring to FIGS. 21 and 28, method 500 includes a block 514 where source/drain regions of the composite fin-shaped structure 2100 are recessed. Operations at block 514 are similar to those described above with respect to block 104. Detailed description of operations at block 514 is omitted for brevity.

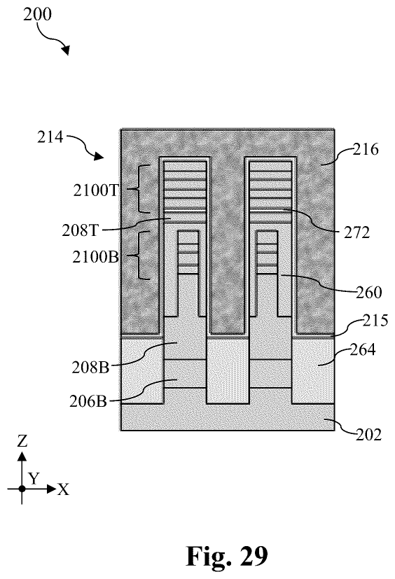

Referring to FIGS. 27 and 29, method 500 includes a block 516 where inner spacer features and a middle dielectric layer 272 are formed. At block 516, the cladding semiconductor layer 260, the sacrificial layers 206 in the bottom portion 2100B and top portion 2100T are selectively etched to form inner spacer recesses. The middle sacrificial layer 206M, which includes a greater germanium content than the sacrificial layers 206, may be substantially removed during the formation of inner spacer recesses to form a space. After the formation of the inner spacer recesses, an inner spacer material layer is deposited over the workpiece 200, including in the inner spacer recesses. Additionally, as shown in FIG. 29, the inner spacer material layer may also be deposited in the space to form the middle dielectric layer 272. The inner spacer material layer may include silicon oxide, silicon nitride, silicon oxycarbide, silicon oxycarbonitride, silicon carbonitride, metal nitride, or a suitable dielectric material. The deposited inner spacer material layer is then etched back to remove excess inner spacer material to form the inner spacer features (not shown in FIG. 29) and the middle dielectric layer 272.

Referring to FIGS. 21 and 29, method 500 includes a block 518 where bottom and top source/drain features are formed. At block 518, bottom source/drain features similar to the bottom source/drain features 242 shown in FIGS. 12A and 12B and top source/drain features similar to the top source/drain features 248 shown in FIGS. 13A and 13b are formed. Operations at block 518 also includes formation of a bottom CESL layer, a bottom ILD layer, a top CESL layer, and a top ILD layer. These operations have been described above with respect to blocks 118, 120, 122, and 124 of method 100. Detailed description of operations at block 518 is omitted. After the bottom and top source/drain features are formed, the dummy gate stack 214 is removed. The removal of the dummy gate stacks 214 may include one or more etching processes that are selective to the material in the dummy gate stacks 214. For example, the removal of the dummy gate stacks 214 may be performed using as a selective wet etch, a selective dry etch, or a combination thereof.

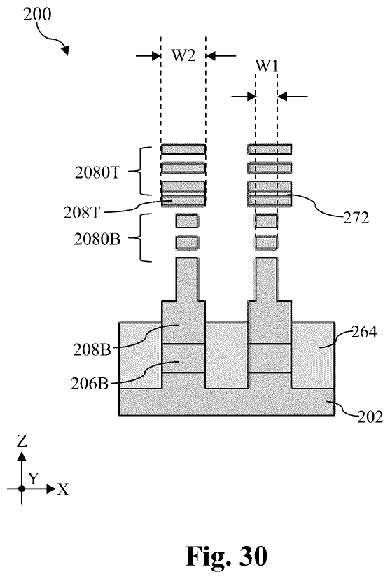

Referring to FIGS. 21 and 30, method 500 includes a block 522 where wide top channel members 2080T and narrow bottom channel members 2080B are released. After the removal of the dummy gate stacks 214, sidewalls of the channel layers 208 and sacrificial layers 206 in the top portion 2100T and bottom portion 2100B of the composite fin-shaped structures 2100 are exposed. Thereafter, the sacrificial layers 206 in the top portion 2100T and bottom portion 2100B are selectively removed to release the channel layers 208 in the bottom portion 2100B as narrow bottom channel members 2080B and the channel layers 208 in the top portion 2100T as wide top channel members 2080T. The narrow bottom channel members 2080B are situated below the middle dielectric layer 272 and top wide channel members 2080T are above the middle dielectric layer 272. The selective removal of the sacrificial layers 206 is described above and will not be repeated here. Reference is still made to FIG. 30. Along the X direction, the narrow bottom channel members 2080B have a first width (W1) and the top wide channel members 2080T have a second width (W2). The second width W2 is greater than the first width W1. In some embodiments, a ratio of the second width W2 to the first width W1 may be between about 1.2 and about 2.2. This range is not trivial. When the ratio is smaller than 1.2, the difference in width may not have sufficient impact on performance. When the ratio is greater than 2.2, it becomes difficult to reach an optimized SRAM performance.

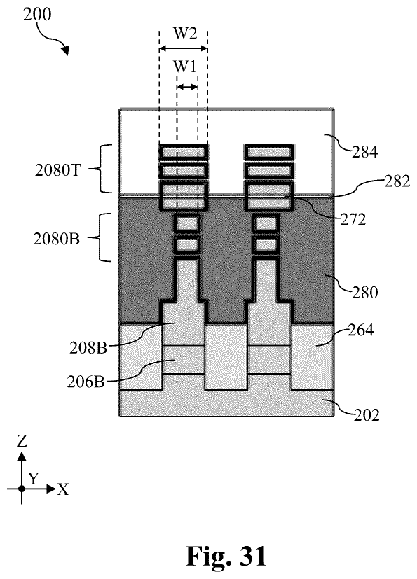

Referring to FIGS. 21 and 31, method 500 includes a block 524 where a bottom gate structure 280 is formed to wrap around each of the narrow bottom channel members 2080B and a top gate structure 284 is formed to wrap around each of the wide top channel members 2080T. Formation of the bottom gate structure 280 and the top gate structure 284 has been described above with respect to block 124 of method 100. At block 524, the bottom gate structure 280, which is a p-type gate structure, is formed to wrap around each of the narrow bottom channel members 2080B. The top gate structure 284, which is an n-type gate structure, is formed to wrap around each of the top wide channel members 2080T. In some embodiments represented in FIG. 31, an insulation layer 282 is deposited over the bottom gate structure 280 before the formation of the top gate structure 284. The insulation layer 282 functions to electrically insulate the bottom gate structure 280 from the top gate structure 284. In some embodiments, the insulation layer 282 includes silicon oxide, silicon oxynitride, silicon nitride, or silicon oxycarbonitride.

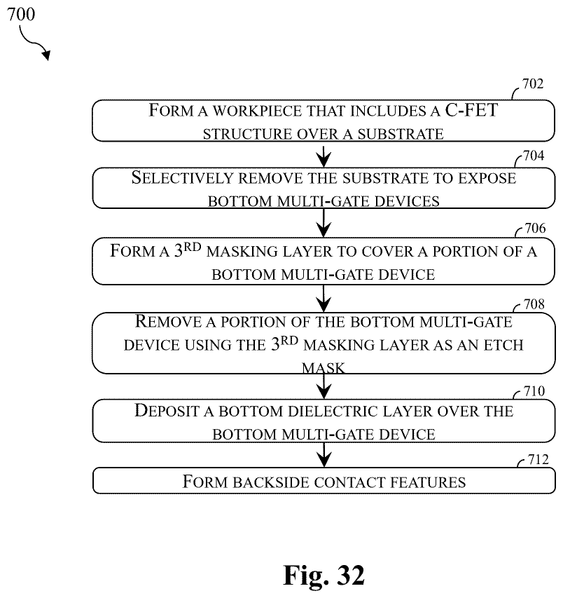

Method 700 in FIG. 32 forms a C-FET where a portion of a bottom multi-gate device is etched to provide not only smaller channel widths but also smaller gate structures.

Referring to FIGS. 32, 33A and 33B, method 700 includes a block 702 where a workpiece 200 is received. The workpiece 200 in FIGS. 33A and 33B includes a C-FET structure that includes a bottom multi-gate device 10 and a top multi-gate device 20. The bottom multi-gate device 10 includes bottom channel members 2080B extending along the X direction between two bottom source/drain features 242. A bottom gate structure 280 wraps around each of the bottom channel members 2080B. The bottom multi-gate device 10 is disposed on a substrate 202. The top multi-gate device 20 includes top channel members 2080T extending along the X direction between two top source/drain features 248. A top gate structure 284 wraps around each of the top channel members 2080T. The top multi-gate device 20 is disposed directly over the bottom multi-gate device 10. Each of the top source/drain features 248 is spaced apart from the bottom source/drain features 242 by the bottom CESL 241 and the bottom ILD layer 243. The bottom gate structure 280 is insulated from the top gate structure 284 by an insulation layer 282. It is noted again that throughout the present disclosure, similar reference numerals are used to denote similar structures. Detailed description of features that have been described may be omitted. Along the Z direction, the bottom gate structure 280 and the top gate structure 284 are spaced apart by a middle portion 210M that includes two channel layers 208 that sandwich a middle dielectric layer 272.

The workpiece in FIGS. 33A and 33B also includes a first source/drain contact 256 and a second source/drain contact 258 in electrical contact with the top source/drain features 248. Each of the first source/drain contact 256 and the second source/drain contact 258 extends through the top CESL 254 and the top ILD layer 255. Each of the first source/drain contact 256 and the second source/drain contact 258 may include a barrier layer and a metal fill. In some embodiments, the barrier layer may include titanium nitride (TiN) or tantalum nitride (TaN) and the metal fill may include cobalt (Co), nickel (Ni), or tungsten (W).

Reference is still made to FIGS. 33A and 33B. Each of the top gate structures 284 may be capped by a self-aligned capping (SAC) layer 292. The bottom gate structure 280 and the top gate structure 284 may be divided into segments by gate cut features 290. The SAC layers 292 and the gate cut features 290 may include silicon nitride, silicon carbonitride, or silicon oxynitride.

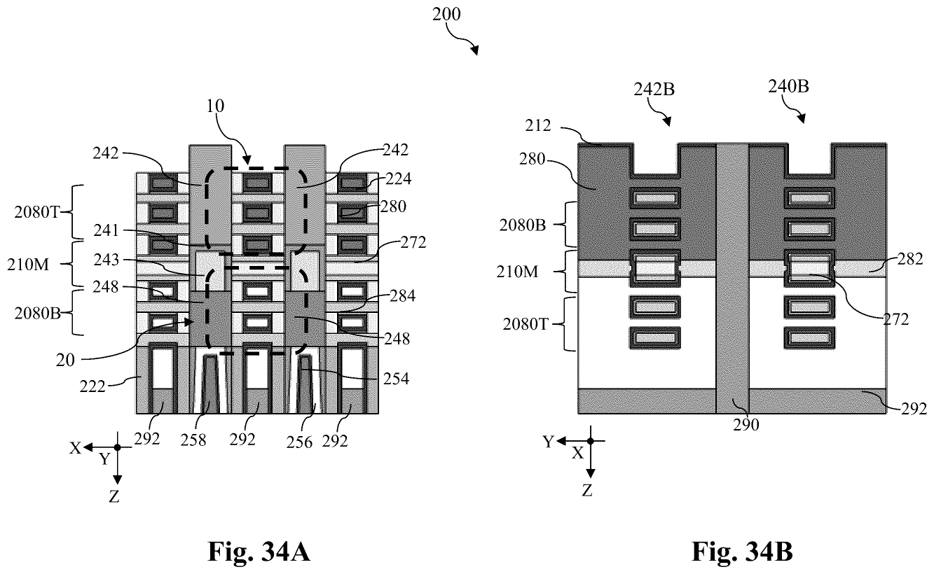

Referring to FIGS. 32, 34A and 34B, method 700 includes a block 704 where a substrate 202 of the workpiece 200 is selectively removed. At block 704, the workpiece 200 is flipped over such that the bottom multi-gate device 10 is directly over the top multi-gate device 20 along the Z direction. The backside of the workpiece 200, including the substrate 202, is thinned by grinding and planarization techniques to reduce a thickness of the substrate 202. The thinned substrate 202 is then selectively removed using a selective wet etch process or a selective dry etch process An example selective wet etch process to etch the substrate 202 may include use of ethylenediamine pyrocatechol (EDP), tetramethylammonium hydroxide (TMAH), nitric acid (HNO₃), hydrofluoric acid (HF), ammonia (NH₃), hydrogen peroxide (H₂O₂), ammonium fluoride (NH₄F) or a suitable wet etchant. An example selective dry etch process to etch the substrate 202 may include sulfur hexafluoride (SF₆), hydrogen (H₂), ammonia (NH₃), hydrogen fluoride (HF), carbon tetrafluoride (CF₄), hydrogen bromide (HBr), argon, or a mixture thereof. Along the X direction, after the removal of the substrate 202, the bottom source/drain features 242, the bottom gate structures 280 from a back side of the workpiece 200, and bottommost (now topmost after the workpiece 200 is flipped upside down) inner spacer features 224 are exposed from a back side of the workpiece 200. Along the Y direction, the base portions of the fin-shaped structures 210 that used to rise above the isolation feature 212 are selectively removed, leaving the isolation feature 212 to define backside recesses 242B that extend into the bottom gate structures 280.

Reference is now made to FIGS. 34A and 34B. After the selective removal of the substrate 202, the isolation feature 212 is selectively removed by a selective wet etch process, such as one that uses hydrofluoric acid (HF) or a buffered hydrofluoric acid solution (BHF).

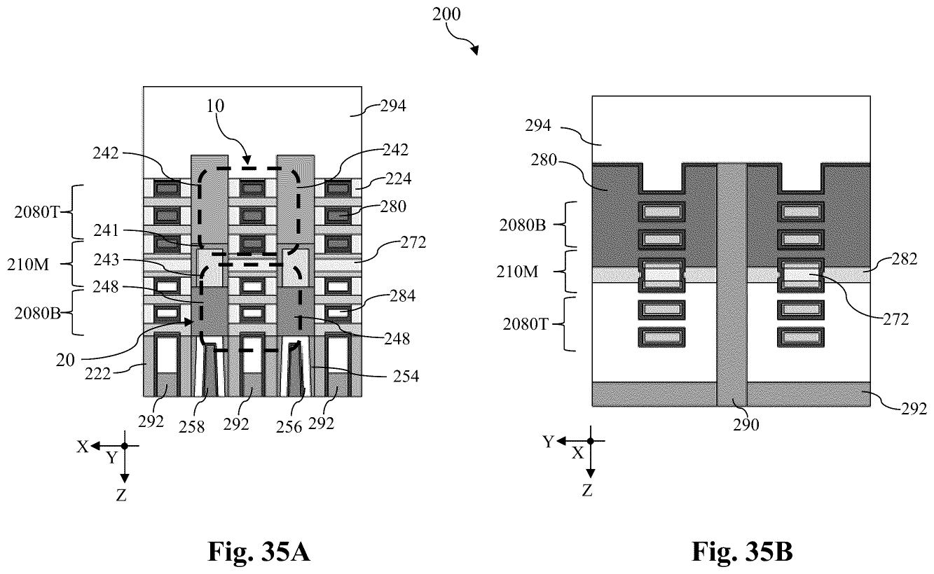

Referring to FIGS. 32, 35A and 35B, method 700 includes a block 706 where a third masking layer 294 is formed over the bottom multi-gate devices 10. In some embodiments, the third masking layer 294 may be a photoresist layer and may be deposited using flowable CVD (FCVD). The third masking layer 294 may be a multilayer. In one embodiment, the third masking layer 294 is a tri-layer and includes a bottom layer, a middle layer disposed over the bottom layer, and a photosensitive layer over the middle layer. After the deposition of the third masking layer 294, a baking process may be performed to cure the third masking layer 294.

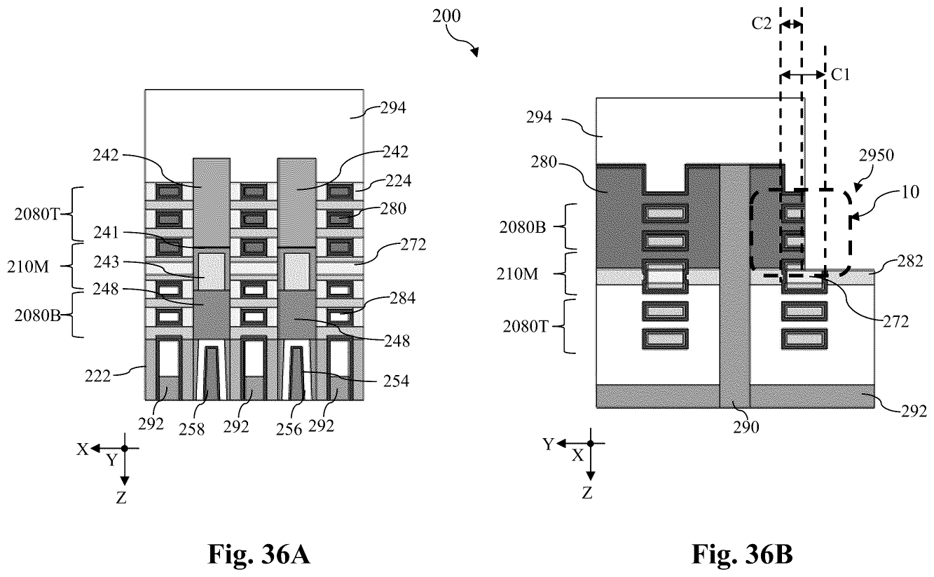

Referring to FIGS. 32, 36A and 36B, method 700 includes a block 708 where a portion of the bottom multi-gate devices 10 is removed using the third masking layer 294 as an etch mask. After the curing of the third masking layer 294, third masking layer 294 may be patterned using photolithography processes to form an etch opening 295 that exposes a portion of one the bottom multi-gate devices 10. The etch opening 295 exposes about one half of the bottom multi-gate device 10. Particularly, along the channel width direction (i.e., the Y direction), the etch opening 295 exposes about one half of the width of the bottom channel members 2080B.

As shown in FIG. 36B, an anisotropic dry etch process may be performed to etch the portion of the bottom multi-gate device 10 exposed in the etch opening 295. An example dry etch process at block 708 may implement an oxygen-containing gas, hydrogen, a fluorine-containing gas (e.g., CF₄, SF₆, NF₃, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. In some embodiments, the etching at block 708 may be time controlled. In some other embodiments, the middle dielectric layer 272 and the insulation layer 282 may serve as an etch stop layer to provide etching end point detection at block 708. As illustrated in FIG. 36B, the anisotropic etching at 708 may remove one half of the bottom multi-gate device 10 to form a device recess 2950. In some embodiments, the operations at block 708 may reduce a channel width of the bottom multi-gate device 10 from a first channel width C1 to a second channel width C2. The second channel width C2 is smaller than the first channel width C1. In some implementations, a ratio of the second channel width C2 to the first channel width C1 may be between about 0.2 and about 0.8. When the ratio is smaller than 0.2, the risk of substantially removing all the bottom channel members 2080B becomes to high. When the ratio is greater than 0.8, the performance difference brought about by this process may not be significant enough to justify the time and cost associated with this process. In one embodiment, the ratio of the second channel width C2 to the first channel width C1 is about 0.5. In this embodiment, about one half of the bottom gate structure 280 for the bottom multi-gate device 10 is removed as well. After the etching the bottom multi-gate device 10, the third masking layer 294 is removed by ashing.

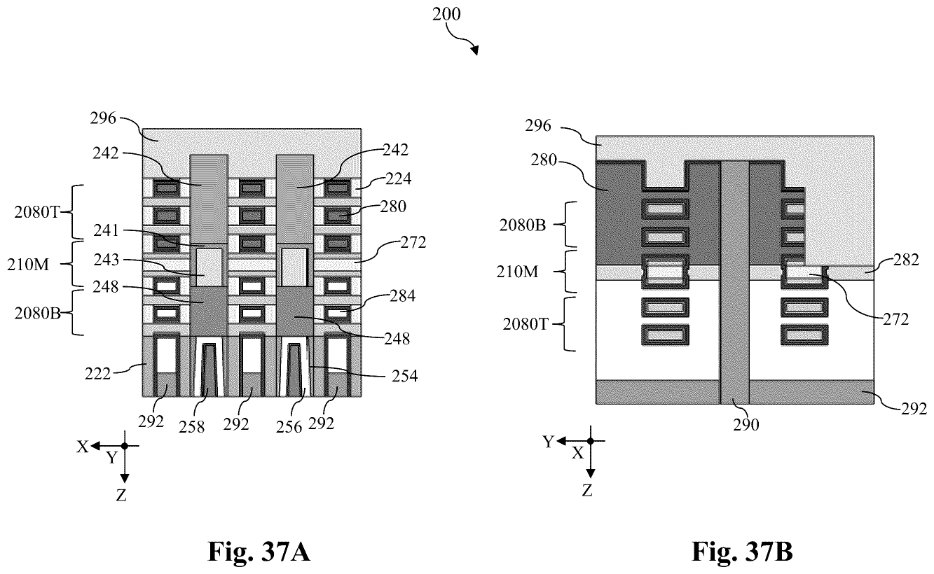

Referring to FIGS. 32, 37A and 37B, method 700 includes a block 710 where a bottom dielectric layer 296 is deposited over the bottom multi-gate device 10. In some embodiments, the bottom dielectric layer 296 may include silicon oxide and may be deposited using FCVD. After the deposition of the bottom dielectric layer 296, the back side of the workpiece 200 is planarized to provide a planar backside surface of the bottom dielectric layer 296, as shown in FIGS. 37A and 37B. Referring to FIG. 37A, the bottom dielectric layer 296 is in direct contact with the bottommost inner spacer features 224, the bottom gate structure 280, and the bottom source/drain features 242. Referring to FIG. 37B, due to the formation of the device recess 2950, a portion of the bottom dielectric layer 296 extend through the bottom gate structure 280 to come in contact with the middle dielectric layer 272 and the insulation layer 282.

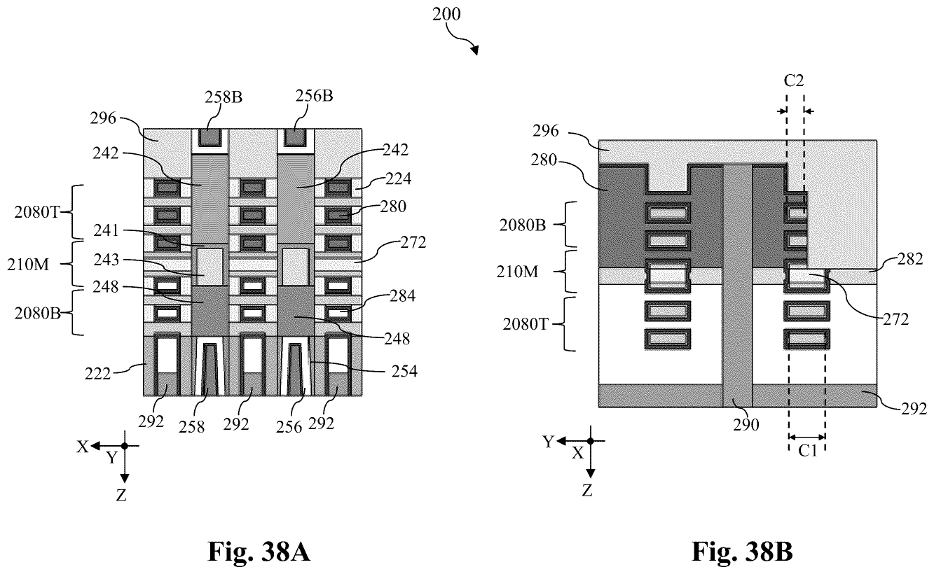

Referring to FIGS. 32, 38A and 38B, method 700 includes a block 712 where backside source/drain contacts 256B and 258B are formed. At block 712, a first backside source/drain contact 256B and a second backside source/drain contact 258B are formed through the bottom dielectric layer 296 to couple to the bottom source/drain features 242. Each of the first backside source/drain contacts 256B and the second backside source/drain contacts 258B extends through the bottom dielectric layer 296. Each of the first backside source/drain contact 256B and the second backside source/drain contact 258B may include a barrier layer and a metal fill. In some embodiments, the barrier layer may include titanium nitride (TiN) or tantalum nitride (TaN) and the metal fill may include cobalt (Co), nickel (Ni), or tungsten (W).

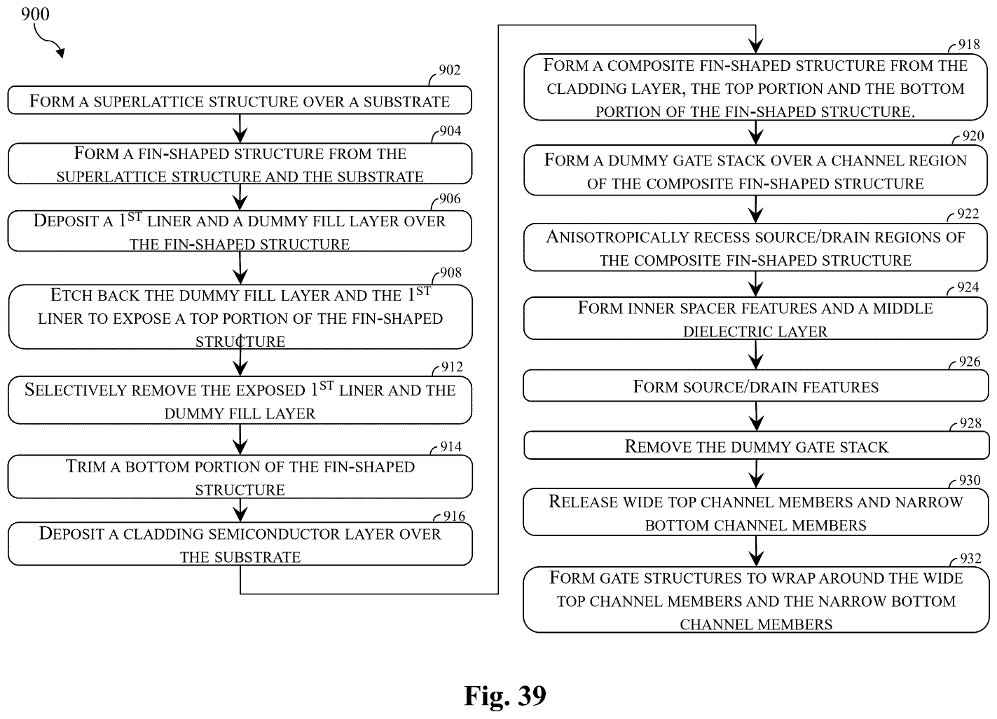

Method 900 in FIG. 39 forms a C-FET using a monolithic process where bottom multi-gate devices have smaller channel widths than top multi-gate devices.

Referring to FIGS. 39 and 40, method 900 includes a block 902 where a superlattice structure 204 is formed over a substrate 202. The workpiece 200 shown in FIG. 40 includes a substrate 202, a bottom silicon germanium layer 206B over the substrate 202, and a bottom silicon layer 208B. Detailed description of the substrate 202, the bottom silicon germanium layer 206B, and the bottom silicon layer 208B has been provided above and will not be repeated here. At block 902, the superlattice structure 204 is formed over the substrate 202 by epitaxially depositing each of the semiconductor layers in the superlattice structure 204. The superlattice structure 204 includes a plurality of channel layers 208 interleaved by a plurality of sacrificial layers 206. The channel layers 208 and the sacrificial layers 206 may have different semiconductor compositions. In some implementations, the channel layers 208 are formed of silicon (Si) and sacrificial layers 206 are formed of silicon germanium (SiGe). In these implementations, the additional germanium content in the sacrificial layers 206 allow selective removal or recess of the sacrificial layers 206 without substantial damages to the channel layers 208. The sacrificial layers 206 and the channel layers 208 are deposited alternatingly, one-after-another, to form the superlattice structure 204. For ease of references, the superlattice structure 204 may be vertically divided into a bottom portion 204BB and a top portion 204TT over the middle portion 204M, with a middle sacrificial layer 206M sandwiched in between. The middle sacrificial layer 206M and the other sacrificial layers may have different germanium contents. In some embodiments, a germanium content of the middle sacrificial layer 206M may be greater than a germanium content of the other sacrificial layers 206 such that the entirety of the middle sacrificial layer 206M may be selectively removed during the formation of inner spacer recesses.

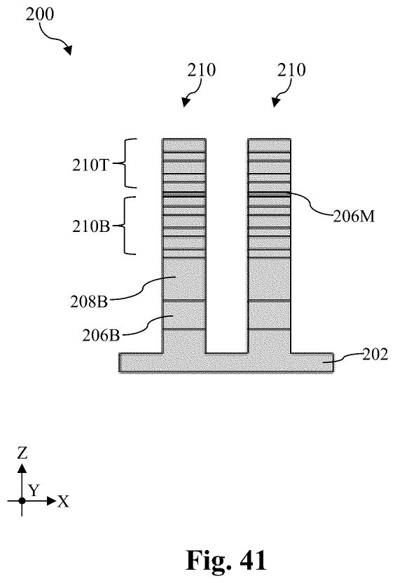

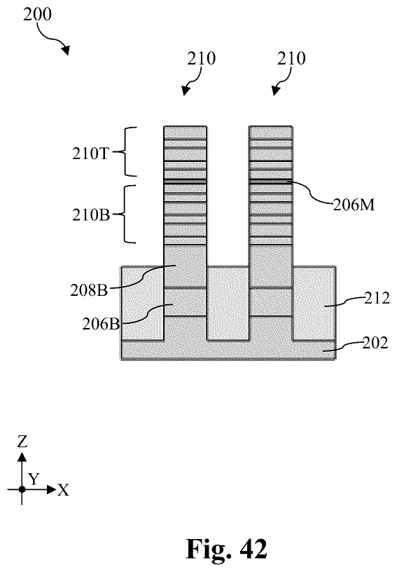

Referring to FIGS. 39, 41 and 42, method 900 includes a block 904 where a fin-shaped structure 210 is formed from the superlattice structure 204, the bottom silicon layer 208B, the bottom silicon germanium layer 206B and the substrate 202. The formation process of the fin-shaped structures 210 is similar to the process used to pattern the fin-shaped structure 210 described above. In some embodiments illustrated in FIG. 41, trenches between fin-shaped structures 210 extend into the substrate 202, Each of the fin-shaped structures 210 in FIG. 41 includes a bottom portion 210B and a top portion 210T. The bottom portion 210b and the top portion 210T are spaced apart from one another by the middle sacrificial layer 206M. Referring to FIG. 42, after the formation of the fin-shaped structure 210, the isolation feature 212 is formed to cover base portions of the fin-shaped structures 210. The isolation feature 212 is in contact with the substrate 202, the bottom silicon germanium layer 206B, and the bottom silicon layer 208B. Detailed description of the formation and the materials of the isolation feature 212 have been provided above and will not be repeated here.

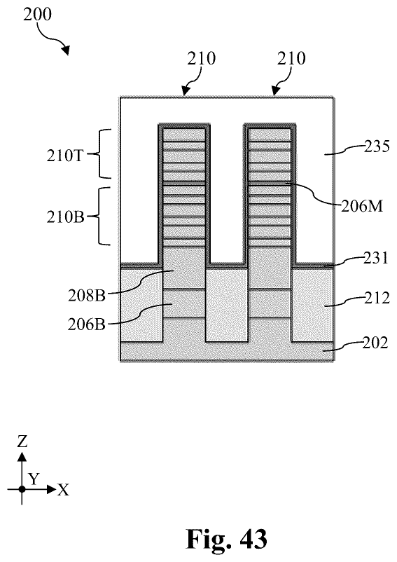

Referring to FIGS. 39 and 43, method 900 includes a block 906 where a first liner 231 and a dummy fill layer 235 are deposited over the fin-shaped structure 210. The first liner 231 includes metal oxide and may be deposited using ALD or CVD. In some embodiments, the first liner 231 includes aluminum oxide. The dummy fill layer 235 may be similar to the dummy fill layer 234 shown in FIGS. 8A and 8B in terms of composition and formation processes. For that reason, detailed description of the dummy fill layer 235 is omitted for brevity.

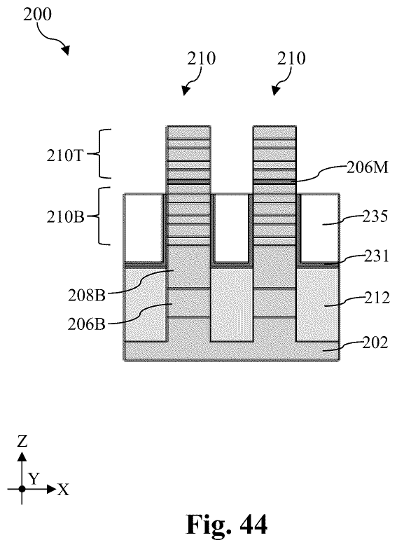

Referring to FIGS. 39 and 44, method 900 includes a block 908 where the first liner 231 and the dummy fill layer 235 are etched back. Operations at block 908 may include etching back of the dummy fill layer 235 and etching back of the first liner 231. The dummy fill layer 235 is etched back using an anisotropic dry etch process. In some embodiments, this dry etch process may include use of hydrogen (H₂), a fluorine-containing gas (e.g., CF₄, SF₆, NF₃, CH₂F₂, CHF₃, and/or C₂F₆), a chlorine-containing gas (e.g., Cl₂, CHCl₃, CCl₄, and/or BCl₃), or a bromine-containing gas (e.g., HBr and/or CHBr₃), an iodine-containing gas. As shown in FIG. 44, the dry etch may be performed until the dummy fill layer 235 only covers the first liner 231 along sidewalls of the bottom portion 210B of the fin-shaped structure 210. The first liner 231 disposed along sidewalls of the middle portion 210M and top portion 210T remains exposed. In other words, the etching back of the dummy fill layer 235 is performed until a top surface of the dummy fill layer 235 is of a level around a boundary of the bottom portion 210B and the middle portion 210M. Referring to FIG. 44, after the recessing of the dummy fill layer 235, the exposed first liner 231 is etched back until top surfaces of the first liner 231 and the dummy fill layer 235 are substantially coplanar. The etching back of the first liner 231 may be performed using a dry etch process, such as one that uses a chlorine-containing gas (e.g., Cl₂, CHCl₃, CCl₄, and/or BCl₃). In some alternative embodiments, the first liner 231 that is not covered by the dummy fill layer 235 may be etched using a wet etch process that uses hydrofluoric acid.

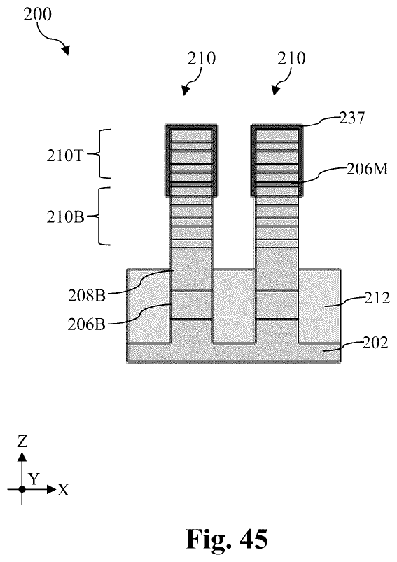

Referring to FIGS. 39 and 45, method 900 includes a block 912 where the first liner 231 and the dummy fill layer 235 are selectively removed. In an example process, a second liner 237 is deposited over the workpiece 200. The second liner 237 is formed of a material that will allow selective removal of the first liner 231 and the dummy fill layer 235. In some embodiments, the second liner 237 includes silicon nitride, silicon oxynitride, or silicon carbide and may be conformally deposited using ALD or CVD. The deposited second liner 237 is then anisotropically etched to expose the dummy fill layer 235. The anisotropic etching may include use of hydrogen (H₂), a fluorine-containing gas (e.g., CF₄, SF₆, NF₃, CH₂F₂, CHF₃, and/or C₂F₆), a chlorine-containing gas (e.g., Cl₂, CHCl₃, CCl₄, and/or BCl₃), or a bromine-containing gas (e.g., HBr and/or CHBr₃), an iodine-containing gas. After the anisotropic etching, the second liner 237 only covers top surfaces and sidewalls of the top portion 210T and the middle portion 210M of the fin-shaped structure 210. With the second liner 237 covering and protecting the top portion 210T and the middle portion 210M of the fin-shaped structure 210, the dummy fill layer 235 and the first liner 231 are removed. In some embodiments, the dummy fill layer 235 and the first liner 231 may be removed in stages. Similar to the etching back operations at block 908, the dummy fill layer 235 and the first liner 231 are removed one by one. The dummy fill layer 235 is first removed and then the first liner 231 is selectively removed after the removal of the dummy fill layer 235. The removal of the first liner 231 and the dummy fill layer 235 exposes sidewalls of the bottom portion 210B of the fin-shaped structure 210.

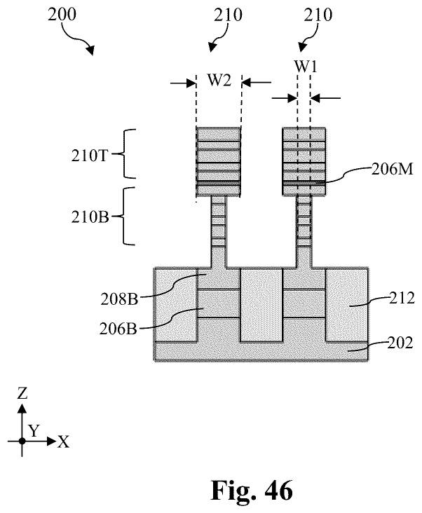

Referring to FIGS. 39 and 46, method 900 includes a block 914 where a bottom portion 210B of the fin-shaped structure 210 is trimmed. In some embodiments, the bottom portion 210B may be trimmed using an isotropic wet etch process. An example wet etch process to trim the bottom portion 210B may include use of ethylenediamine pyrocatechol (EDP), tetramethylammonium hydroxide (TMAH), nitric acid (HNO₃), hydrofluoric acid (HF), ammonia (NH₃), hydrogen peroxide (H₂O₂), ammonium fluoride (NH₄F) or a suitable wet etchant. In some embodiments represented in FIG. 46, the bottom portion 210B may be trimmed to have a first width W1 while the top portion 210T has a second width W2. In some embodiments, a ratio of the second width W2 to the first width W1 may be between about 1.2 and about 2.2. This range is not trivial. When the ratio is smaller than 1.2, the difference in width may not have sufficient impact on performance. When the ratio is greater than 2.2, it becomes difficult to reach an optimized SRAM performance. Referring to FIG. 46, after the bottom portion 210B is trimmed, the second liner 237 is removed by selective etching. In embodiments wherein the second liner 237 includes silicon nitride, the second liner 237 may be selectively removed using phosphoric acid.

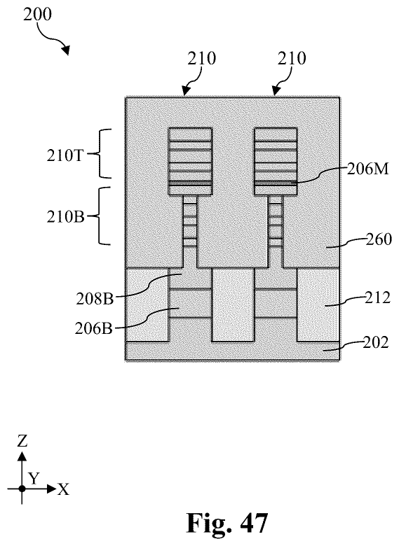

Referring to FIGS. 39 and 47, method 900 includes a block 916 where a cladding semiconductor layer 260 is deposited over the fin-shaped structures 210. The cladding semiconductor layer 260 is similar to the cladding semiconductor layer 260 described above in conjunction with FIGS. 24 and 25. Detailed description of the cladding semiconductor layer 260 is therefore omitted for brevity. As shown in FIG. 47, the cladding semiconductor layer 260 is deposited to contact the isolation feature 212, the bottom portion 210B and the top portion 210T.

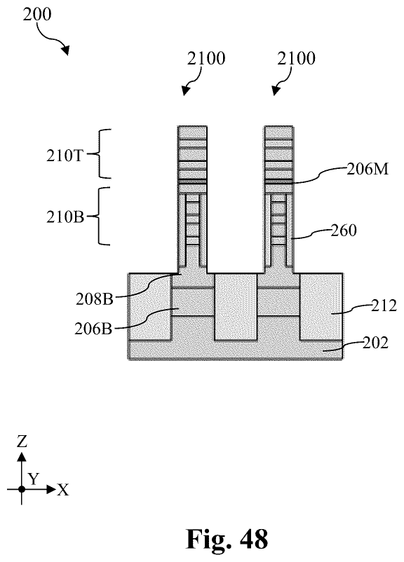

Referring to FIGS. 39 and 48, method 900 includes a block 918 where composite fin-shaped structures 2100 are formed. Operations at block 918 may be similar to those described above at block 508. Detailed description of the operations at block 920 is omitted for brevity. It is noted that because the bottom portion 210B in FIG. 48 is isotropically trimmed when the top portion 210T is covered, center lines of the narrower bottom portion 210B are substantially aligned with the wider top portion 210T. The same cannot be said with the bottom portion 2100B and top portion 2100T shown in FIG. 30. In FIG. 30, the top portion 2100T only needs to vertically overlap the bottom portion 2100B. Their center lines are not necessarily aligned. In most embodiments, their center lines are not aligned.

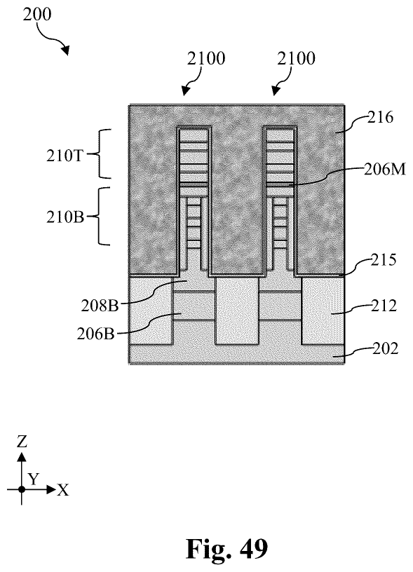

Referring to FIGS. 39 and 49, method 900 includes a block 920 where a dummy gate stack 214 is formed over channel regions of the composite fin-shaped structures 2100. Operations at block 920 are similar to those described above with respect to block 102. Detailed description of operations at block 920 is omitted for brevity.

Referring to FIGS. 39 and 49, method 900 includes a block 922 where source/drain regions of the composite fin-shaped structure 2100 are anisotropically recessed. Operations at block 922 are similar to those described above with respect to block 104. Detailed description of operations at block 922 is omitted for brevity.

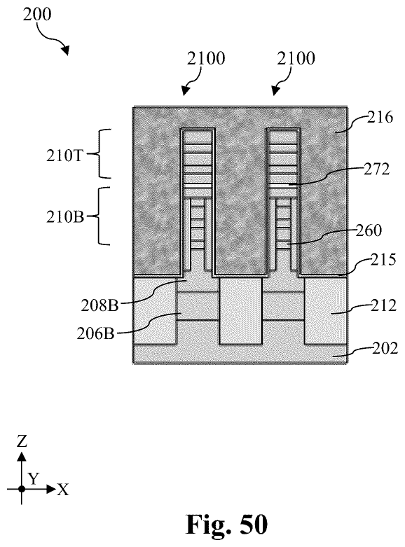

Referring to FIGS. 39 and 50, method 900 includes a block 924 where inner spacer features and a middle dielectric layer 272 are formed. Operations at block 924 are similar to those described above with respect to block 516. Detailed description of operations at block 924 is omitted for brevity.

Referring to FIGS. 39 and 50, method 900 includes a block 926 where source/drain feature are formed over the source/drain regions. Operations at block 926 are similar to those described above with respect to block 518. Detailed description of operations at block 926 is omitted for brevity.

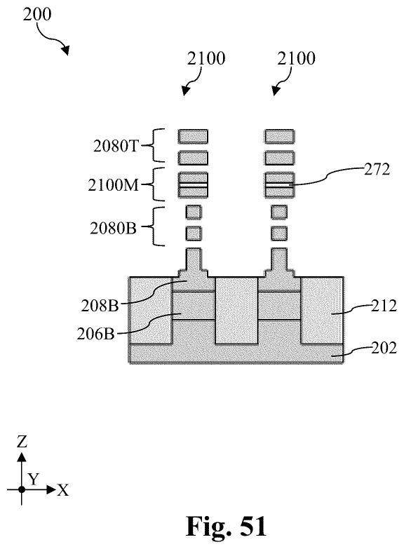

Referring to FIGS. 39 and 51, method 900 includes a block 928 where the dummy gate stack 214 is removed. The removal of the dummy gate stacks 214 may include one or more etching processes that are selective to the material in the dummy gate stacks 214. For example, the removal of the dummy gate stacks 214 may be performed using as a selective wet etch, a selective dry etch, or a combination thereof.

Referring to FIGS. 39 and 51, method 900 includes a block 930 where wide top channel members 2100T and narrow bottom channel members 2100B are released. Operations at block 930 are similar to those described above with respect to block 522. Detailed description of operations at block 930 is omitted for brevity. The top channel members 2100T and the bottom channel members 2100B are vertically spaced apart by a middle portion 2100B, which includes two channel layers 208 sandwiching the middle dielectric layer 272.

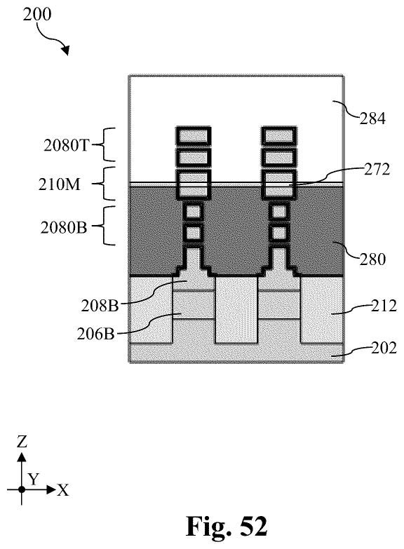

Referring to FIGS. 39 and 52, method 900 includes a block 932 where a bottom gate structure 280 is formed to wrap around each of the narrow bottom channel members 2100B and a top gate structure 284 is formed to wrap around each of the wide top channel members 2100T. Operations at block 932 are similar to those described above with respect to block 524. Detailed description of operations at block 932 is omitted for brevity.

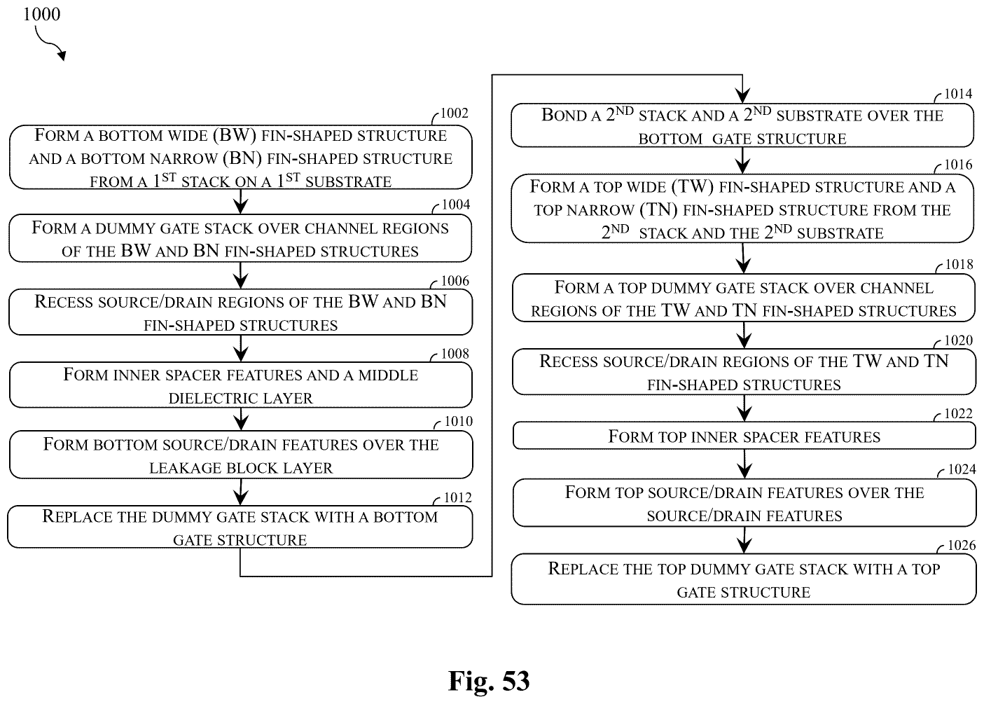

Method 1000 in FIG. 53 forms a C-FET using a sequential process where multi-gate devices on a bottom level and a top level have more than one channel widths. In method 100, bottom multi-gate devices with different channel widths are first formed on a first substrate 202B from a first stack 2040B and then a second substrate 202T with a second stack 2040T is bonded over the bottom multi-gate devices. Top multi-gate devices with different channel widths are then formed from the second stack 2040T. Because many of the operations in method 1000 have been described above in conjunction with methods 100, 300, 500, 700, and 900, description of some operations in method 1000 may be brief to avoid redundancy.

Referring to FIGS. 53, 54A and 54B, method 1000 includes a block 1002 where a bottom wide fin-shaped structure 210W and a bottom narrow fin-shaped structure 210N are formed from a first stack 2040B over a first substrate 202B. The first substrate 202B may be similar to the substrate 202 described above. In some embodiments illustrated in FIGS. 54A and 54B, a bottom silicon germanium layer 206B is deposited on the first substrate 202B, a bottom silicon layer 208B is deposited on the bottom silicon germanium layer 206B, and the first stack 2040B is deposited on the bottom silicon layer 208B. The first stack 2040B includes channel layers 208 interleaved by sacrificial layers 206. Detailed description of formation and composition of the first substrate 202B, the bottom silicon layer 208B, the bottom silicon germanium layer 206B, the channel layers 208, and the sacrificial layers 206 is omitted for brevity.

At block 1002, a bottom wide fin-shaped structure 210W and a bottom narrow fin-shaped structure 210N are patterned from the first stack 2040B, the bottom silicon layer 208B, the bottom silicon germanium layer 206B, and a portion of the first substrate 202B. As shown in FIG. 54B, the bottom narrow fin-shaped structure 210N has a third width W3 along the X direction and the bottom wide fin-shaped structure 210W has a fourth width W4 along the X direction. The fourth width W4 is greater than the third width W3.

Referring to FIGS. 53, 54A and 54B, method 1000 includes a block 1004 where dummy gate stacks 214 are formed over the bottom wide fin-shaped structure 210W and the bottom narrow fin-shaped structure 210N. Operations at block 1004 are similar to those described above with respect to block 102. Detailed description of operations at block 1004 is omitted for brevity. As shown in FIGS. 54A and 54B, the dummy gate stacks 214 are formed over channel regions of the bottom wide fin-shaped structure 210W and the bottom narrow fin-shaped structure 210N.

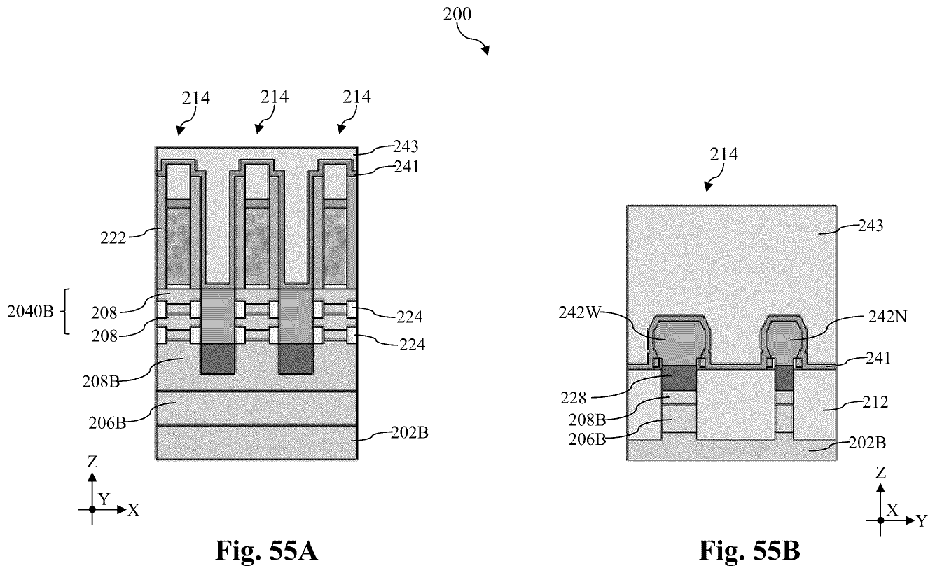

Referring to FIGS. 53, 55A and 55B, method 1000 includes a block 1006 where source/drain regions of the bottom wide fin-shaped structure 210W and the bottom narrow fin-shaped structure 210N are recessed. Operations at block 1006 are similar to those described above with respect to block 104. Detailed description of operations at block 1006 is omitted for brevity.

Referring to FIGS. 53, 55A and 55B, method 1000 includes a block 1008 where inner spacer features 224 are formed. Operations at block 1008 are similar to those described above with respect to block 104. Detailed description of operations at block 1008 is omitted for brevity.

Referring to FIGS. 53, 55A and 55B, method 1000 includes a block 1010 where bottom source/drain features 242W and 242N are formed. Deposition of the bottom wide source/drain feature 242W and bottom narrow source/drain feature 242N takes place after the formation of the leakage block layer 228. Because operations for forming the leakage block layer 228 has been described above with respect to block 106 of method 100, they will not be described in detail again. The deposition of the bottom wide source/drain feature 242W and bottom narrow source/drain feature 242N is similar to the deposition of the high-strain bottom source/drain feature 242 described above with respect to block 118 of method 100. Detailed description thereof is omitted here for brevity. It is noted that, due to the nature of the epitaxial growth, the wider bottom wide fin-shaped structure 210W gives rise to wider bottom wide source/drain feature 242W while the narrower bottom narrow fin-shaped structure 210N gives rise to narrower bottom narrow source/drain feature 242N. In some embodiments, bottom narrow source/drain feature 242N and bottom wide source/drain feature 242W are p-type source/drain features and may include silicon germanium and a p-type dopant, such as boron (B).

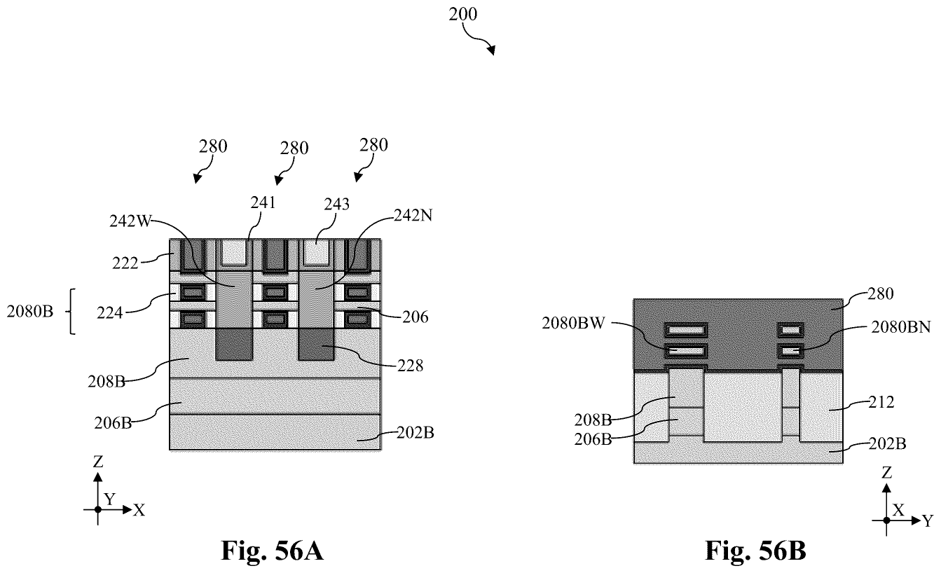

Referring to FIGS. 53, 56A and 56B, method 1000 includes a block 1012 where the dummy gate stacks 214 are replaced with a bottom gate structure 280. Operations at block 1012 may include removal of the dummy gate stacks 214, release of the channel layers 208 as bottom wide channel members 2080BW and bottom narrow channel members 2080BN, and formation of the bottom gate structure 280 to wrap around each of the bottom wide channel members 2080BW and bottom narrow channel members 2080BN. With the exception of the channel widths of the bottom wide channel members 2080BW and the bottom narrow channel members 2080BN, these operations have been similarly described above and will not be repeated here. In some embodiments, the bottom gate structure 280 is a p-type gate structure.

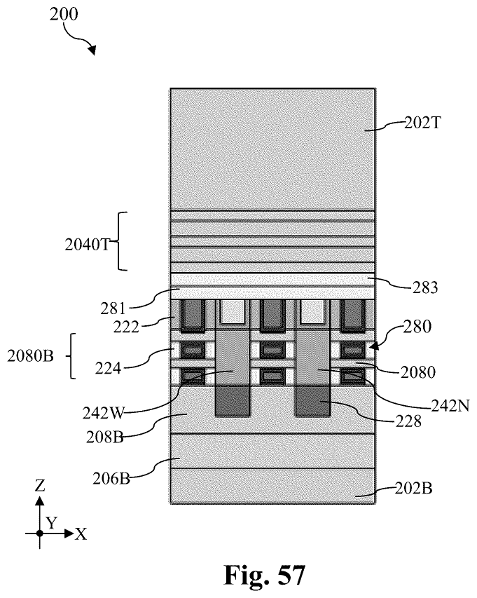

Referring to FIGS. 53 and 57, method 1000 includes a block 1014 where a second stack 2040T and a second substrate 202T are bonded over the bottom gate structure 280. The second stack 2040T is formed over the second substrate 202T. The second substrate 202T and the second stack 2040T are flipped upside down to bond to the bottom gate structure 280. To achieve such a bonding, a first bonding layer 281 is deposited over the bottom gate structure 280 using CVD and a second bonding layer 283 is deposited over the second stack 2040T using CVD. In some embodiments, the first bonding layer 281 and the second bonding layer 283 may include silicon oxide or silicon oxynitride. A direct bonding process is then performed to bond the second bonding layer 283 to the first bonding layer 281. To ensure a strong bonding between the second bonding layer 283 to the first bonding layer 281, surfaces of the second bonding layer 283 to the first bonding layer 281 are cleaned to remove organic and metallic contaminants. In an example process, a sulfuric acid hydrogen peroxide mixture (SPM), a mixture of ammonium hydroxide and hydrogen peroxide (SC1), or both may be used to remove organic contaminants the second bonding layer 283 to the first bonding layer 281. A mixture of hydrochloric acid and hydrogen peroxide (SC2) may be used to remove metallic contaminants. The second bonding layer 283 is then brought to direct contact with the first bonding layer 281. An anneal is performed to promote the van der Waals force bonding of the second bonding layer 283 to the first bonding layer 281. After the bonding process, the second substrate 202T may be removed by grinding, chemical mechanical polishing, or a combination thereof.

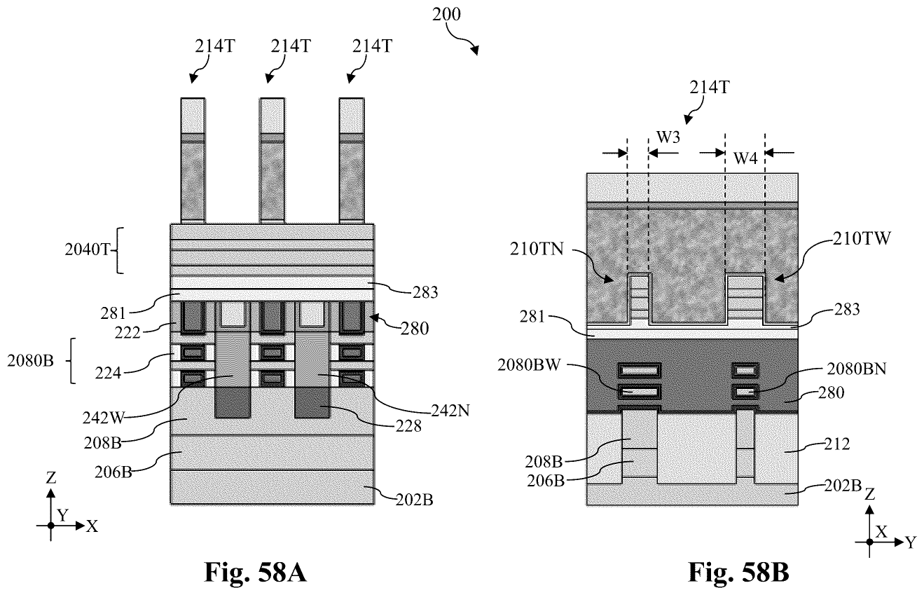

Referring to FIGS. 53, 58A and 58B, method 1000 includes a block 1016 where a top narrow fin-shaped structure 210TN and a top wide fin-shaped structure 210TW are formed from a second stack 2040T over a second substrate 202T. In a fashion similar to the formation of the bottom wide fin-shaped structure 210W and the bottom narrow fin-shaped structure 210N, the second stack 2040T is patterned to form the top narrow fin-shaped structure 210TN and the top wide fin-shaped structure 210TW. As shown in FIG. 58B, the top narrow fin-shaped structure 210TN has a third width W3 along the X direction and the top wide fin-shaped structure 210TW has a fourth width W4 along the X direction. The fourth width W4 is greater than the third width W3. In some embodiments represented in FIG. 58B, the top wide fin-shaped structure 210TW is disposed directly over the bottom wide channel members 2080BW and the top narrow fin-shaped structure 210TN is disposed directly over the bottom narrow channel members 2080BN.

Referring to FIGS. 53, 58A and 58B, method 1000 includes a block 1018 where top dummy gate stacks 214T are formed over channel region of the top narrow fin-shaped structure 210TN and the top wide fin-shaped structure 210TW. Operations at block 1018 are similar to those described above with respect to block 102. Detailed description of operations at block 1018 is omitted for brevity. As shown in FIGS. 58A and 58B, the top dummy gate stacks 214T are formed over channel regions of the top wide fin-shaped structure 210TW and the top narrow fin-shaped structure 210TN.

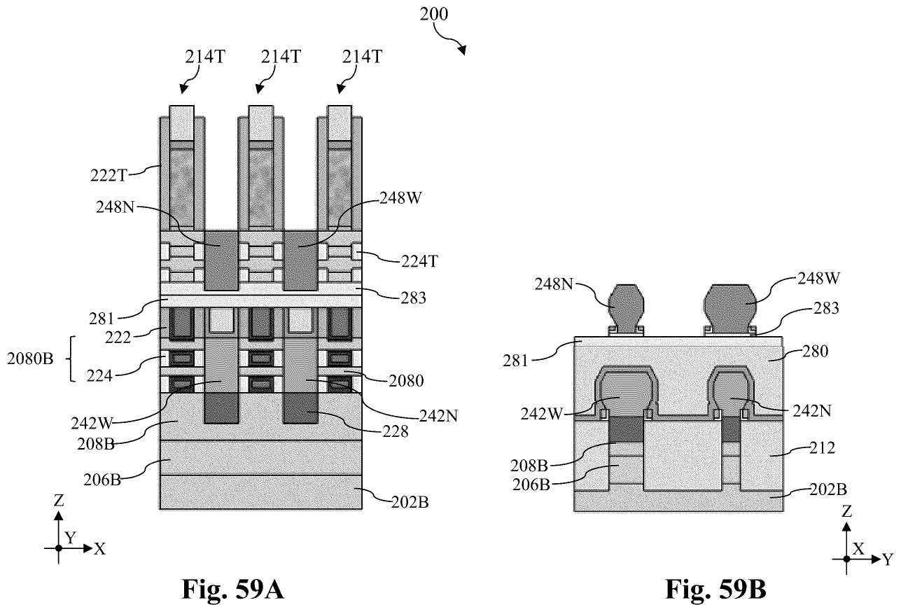

Referring to FIGS. 53, 59A and 59B, method 1000 includes a block 1020 where source/drain regions of the top narrow fin-shaped structure 210TN and the top wide fin-shaped structure 210TW are recessed. Operations at block 1020 are similar to those described above with respect to block 104. Detailed description of operations at block 1020 is omitted for brevity. Different from the operation at block 104, the source/drain recessing at block 102 terminates at a level that falls within the second bonding layer 283. That is, the second bonding layer 283 serves as an etch stop layer for the recessing at block 1020.

Referring to FIGS. 53, 59A and 59B, method 1000 includes a block 1022 where top inner spacer features 224T are formed. Operations at block 1022 are similar to those described above with respect to block 104. Detailed description of operations at block 1008 is omitted for brevity. In the depicted embodiments, composition of the top inner spacer features 224T is similar to that of the inner spacer features 224.

Referring to FIGS. 53, 59A and 59B, method 1000 includes a block 1024 where a top narrow source/drain feature 248N and a top wide source/drain feature 248W are formed. The deposition of the top wide source/drain feature 248W and top narrow source/drain feature 248N is similar to the deposition of the top source/drain feature 248 described above with respect to block 122 of method 100. Detailed description thereof is omitted here for brevity. It is noted that, due to the nature of the epitaxial growth, the wider top wide fin-shaped structure 210TW gives rise to wider top wide source/drain feature 248W while the narrower top narrow fin-shaped structure 210TN gives rise to narrower top narrow source/drain feature 248N. In some embodiments, top narrow source/drain feature 248N and top wide source/drain feature 248W are n-type source/drain features and may include silicon and an n-type dopant, such as phosphorus (P).

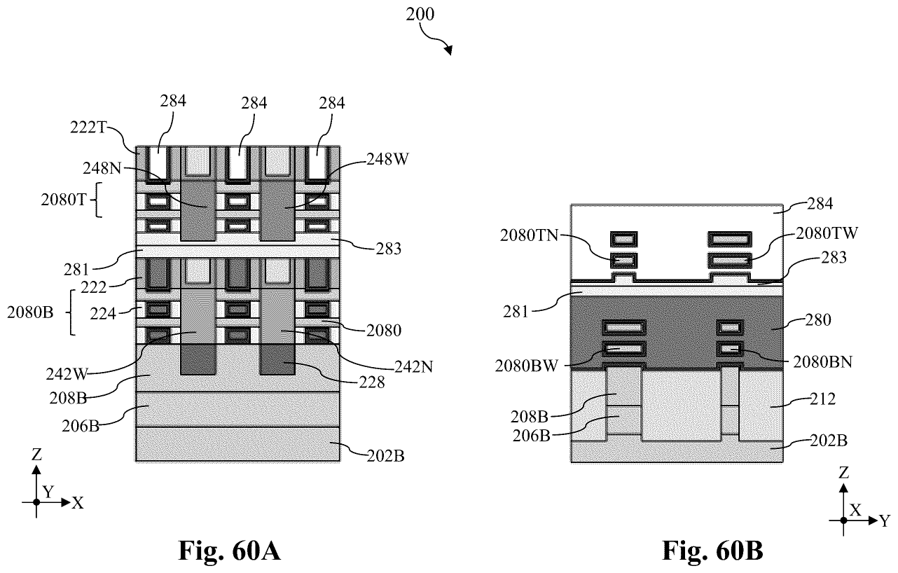

Referring to FIGS. 53, 60A and 60B, method 1000 includes a block 1026 where the top dummy gate stacks 214T are replaced with top gate structures 284. Operations at block 1026 may include removal of the top dummy gate stacks 214T, release of the channel layers 208 as top wide channel members 2080TW and top narrow channel members 2080TN, and formation of the top gate structure 284 to wrap around each of the top wide channel members 2080TW and top narrow channel members 2080TN. With the exception of the channel widths of the top wide channel members 2080TW and top narrow channel members 2080TN, these operations have been similarly described above and will not be repeated here. In some embodiments, the top gate structure 284 is an n-type gate structure.

In one exemplary aspect, the present disclosure is directed to a semiconductor device. The semiconductor device includes a substrate, a first semiconductor layer over the substrate, a second semiconductor layer over the first semiconductor layer and including a channel region sandwiched between a first source/drain region and a second source/drain region, a first plurality of nanostructures disposed over the channel region, a first leakage block layer disposed over the first source/drain region, a second leakage block layer disposed over the second source/drain region, a dielectric layer disposed on the first leakage block layer, a first source/drain feature disposed on the dielectric layer and in contact with first sidewalls of the first plurality of nanostructures, and a second source/drain feature disposed on the second leakage block layer and in contact with second sidewalls of the first plurality of nanostructures. The first leakage block layer and the second leakage block layer include an undoped semiconductor material.

In some embodiments, the first source/drain feature and the second source/drain feature include silicon germanium (SiGe) and a p-type dopant. In some embodiments, the substrate and the second semiconductor layer include silicon (Si) and the first semiconductor layer includes silicon germanium (SiGe). In some implementations, the first leakage block layer and the second leakage block layer include undoped germanium (Ge) or undoped silicon germanium (SiGe). In some embodiments, the dielectric layer include silicon nitride. In some instances, the semiconductor structure further includes a first gate structure wrapping around at least one of the first plurality of nanostructures, a middle dielectric layer over the first plurality of nanostructures, a second plurality of nanostructures over the middle dielectric layer, and a second gate structure wrapping around at least one of the second plurality of nanostructures. A composition of the first gate structure is different from a composition of the second gate structure. In some embodiments, the first gate structure includes titanium nitride (TiN), tantalum nitride (TaN), ruthenium (Ru), molybdenum (Mo), aluminum (Al), tungsten nitride (WN), zirconium silicide (ZrSi₂), molybdenum silicide (MoSi₂), tantalum silicide (TaSi₂), or nickel silicide (NiSi₂) and the second gate structure includes titanium (Ti), aluminum (Al), silver (Ag), manganese (Mn), zirconium (Zr), titanium aluminum (TiAl), titanium aluminum carbide (TiAlC), tantalum carbide (TaC), tantalum carbonitride (TaCN), tantalum silicide nitride (TaSiN), tantalum aluminum (TaAl), tantalum aluminum carbide (TaAlC), or titanium aluminum nitride (TiAlN). In some instances, the semiconductor structure further includes a third source/drain feature disposed over the first source/drain feature and a fourth source/drain feature disposed over the second source/drain feature. The second plurality of nanostructures are sandwiched between and in contact with the third source/drain feature and the fourth source/drain feature. In some embodiments, the third source/drain feature and the fourth source/drain feature include silicon (Si) and an n-type dopant.

In another exemplary aspect, the present disclosure is directed to a semiconductor structure. The semiconductor structure includes a substrate, a first fin and a second fin rising from the substrate and spaced apart from one another by an isolation feature, a first leakage block layer over the first fin, a second leakage block layer over the second fin, first spacer features disposed along sidewalls of the first leakage block layer, second spacer features disposed along sidewalls of the second leakage block layer, a dielectric layer disposed over the first spacer features, the first leakage block layer and a portion of the isolation feature, a first source/drain feature disposed over the dielectric layer, and a second source/drain feature disposed over the second leakage block layer and the second spacer features. The first source/drain feature is spaced apart from the first leakage block layer and the first spacer features by the dielectric layer. The second source/drain feature is in direct contact with the second leakage block layer and the second spacer features.

In some embodiments, the first source/drain feature and the second source/drain feature include silicon germanium (SiGe) and a p-type dopant. In some implementations, the dielectric layer include silicon nitride. In some embodiments, the first leakage block layer and the second leakage block layer include undoped germanium (Ge) or undoped silicon germanium (SiGe). In some embodiments, each of the first fin and the second fin includes a base portion rising from the substrate, a middle portion formed of a first semiconductor material, and a top portion formed of a second semiconductor material. The substrate and the top portion include silicon (Si) and the middle portion includes silicon germanium (SiGe). In some embodiments, the semiconductor structure further includes a contact etch stop layer (CESL) disposed over the dielectric layer, the first source/drain feature, the isolation feature, the second spacer features, and the second source/drain feature. The CESL is in direct contact with the dielectric layer, the first source/drain feature, the isolation feature, the second spacer features, and the second source/drain feature. In some embodiments, the CESL is spaced apart from the first spacer features by the dielectric layer.

In yet another exemplary aspect, the present disclosure is directed to a method. The method includes receiving a workpiece that includes a fin-shaped structure extending lengthwise along a direction, the fin-shaped structure including bottom sacrificial layers interleaved by bottom channel layers, a middle semiconductor layer over a topmost one of the bottom channel layers, and top sacrificial layers interleaved by top channel layers, a dummy gate stack over a channel region of the fin-shaped structure, and top gate spacers disposed along sidewalls of the dummy gate stack, anisotropically etching a first source/drain region and a second source/drain region of the fin-shaped structure to form a first source/drain recess and a second source/drain recess, respectively, the first source/drain region and the second source/drain region sandwiching the channel region, sidewalls of the bottom channel layers and top channel layers being exposed in the first source/drain recess and the second source/drain recess, forming a first leakage block layer over the first source/drain recess and a second leakage block layer over the second source/drain recess, conformally depositing a sealing layer over dummy gate stack, the top gate spacers, the first leakage block layer, and the second leakage block layer, selectively removing the sealing layer over the second leakage block layer to expose the second leakage block layer, forming a first source/drain feature in contact with the sidewalls of the bottom channel layers and over the sealing layer, and forming a second source/drain feature in contact with the sidewalls of the bottom channel layers and over the second leakage block layer.

In some embodiments, the method further includes depositing a bottom contact etch stop layer (CESL) over the first source/drain feature and the second source/drain feature, depositing a bottom interlayer dielectric layer (ILD) over the bottom CESL, forming a third source/drain feature over the ILD and the first source/drain feature, and forming a fourth source/drain feature over the ILD and the second source/drain feature. In some embodiments, the first leakage block layer and the second leakage block layer include undoped semiconductor material. In some instances, the sealing layer includes silicon nitride.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a substrate;
an isolation feature over the substrate;
a first base fin and a second base fin extending from the substrate and rising over the isolation feature;
a first leakage block layer over the first base fin;
a second leakage block layer over the second base fin;
a first lopsided source/drain feature over the first leakage block layer;
a second lopsided source/drain feature over the second leakage block layer;
a bottom contact etch stop layer (CESL) over the first leakage block layer, the first lopsided source/drain feature, the second leakage block layer, and the second lopsided source/drain feature;
a bottom interlayer dielectric (ILD) layer over the bottom CESL;
a first top source/drain feature over the bottom ILD layer and being directly over the first lopsided source/drain feature; and
a second top source/drain feature over the bottom ILD layer and being directly over the second lopsided source/drain feature,
wherein the bottom CESL interfaces the first leakage block layer and the second leakage block layer.

2. The semiconductor structure of claim 1,
wherein the first lopsided source/drain feature comprises a first vertical sidewall extending from the first leakage block layer,
wherein the second lopsided source/drain feature comprises a second vertical sidewall extending from the second leakage block layer.

3. The semiconductor structure of claim 2, wherein the first vertical sidewall and the second vertical sidewall are facing away from one another.

4. The semiconductor structure of claim 2, wherein the bottom CESL is disposed along the first vertical sidewall and the second vertical sidewall.

5. The semiconductor structure of claim 1, wherein the first base fin and the second base fin comprise:
a bottom portion formed from the substrate;
a middle portion over the bottom portion, the middle portion being formed from a first semiconductor layer; and
a top portion over the middle portion, the top portion being formed from a second semiconductor layer.

6. The semiconductor structure of claim 5,
wherein the bottom portion comprises silicon,
wherein the middle portion comprises silicon germanium,
wherein the top portion comprises silicon.

7. The semiconductor structure of claim 1, wherein the first leakage block layer and the second leakage block layer comprise undoped silicon (Si), undoped silicon germanium (SiGe), or undoped germanium (Ge).

8. The semiconductor structure of claim 1,
wherein the first base fin and the second base fin are spaced apart from one another along a first direction,
wherein the first leakage block layer is disposed between a first gate spacer feature and a second gate spacer feature,
wherein the second leakage block layer is disposed between a third gate spacer feature and a fourth gate spacer feature.

9. The semiconductor structure of claim 8,
wherein top surfaces of the first gate spacer feature and the second gate spacer feature are higher than a top surface of the first leakage block layer,
wherein top surfaces of the third gate spacer feature and the fourth gate spacer feature are higher than a top surface of the second leakage block layer.

10. The semiconductor structure of claim 8,
wherein the first lopsided source/drain feature overhangs the second gate spacer feature but does not overhang the first gate spacer feature,
wherein the second lopsided source/drain feature overhangs the third gate spacer feature but does not overhang the fourth gate spacer feature.

11. A semiconductor structure, comprising:
a substrate;
an isolation feature over the substrate;
a first base fin and a second base fin extending from the substrate and rising over the isolation feature, the first base fin and the second base fin being spaced apart from one another along a direction;
a first leakage block layer over the first base fin;
a second leakage block layer over the second base fin;
a first lopsided source/drain feature over the first leakage block layer;
a second lopsided source/drain feature over the second leakage block layer;
a bottom contact etch stop layer (CESL) over the first leakage block layer, the first lopsided source/drain feature, the second leakage block layer, and the second lopsided source/drain feature;
a bottom interlayer dielectric (ILD) layer over the bottom CESL;
a first top source/drain feature over the bottom ILD layer and being directly over the first lopsided source/drain feature; and
a second top source/drain feature over the bottom ILD layer and being directly over the second lopsided source/drain feature,
wherein the first leakage block layer is disposed between a first gate spacer feature and a second gate spacer feature,
wherein the second leakage block layer is disposed between a third gate spacer feature and a fourth gate spacer feature,
wherein the first lopsided source/drain feature overhangs the second gate spacer feature but does not overhang the first gate spacer feature,
wherein the second lopsided source/drain feature overhangs the third gate spacer feature but does not overhang the fourth gate spacer feature.

12. The semiconductor structure of claim 11, wherein the bottom CESL interfaces the first leakage block layer and the second leakage block layer.

13. The semiconductor structure of claim 11,
wherein top surfaces of the first gate spacer feature and the second gate spacer feature are higher than a top surface of the first leakage block layer,
wherein top surfaces of the third gate spacer feature and the fourth gate spacer feature are higher than a top surface of the second leakage block layer.

14. The semiconductor structure of claim 11,
wherein the first lopsided source/drain feature comprises a first vertical sidewall extending from the first leakage block layer,
wherein the second lopsided source/drain feature comprises a second vertical sidewall extending from the second leakage block layer,
wherein the first vertical sidewall and the second vertical sidewall are facing away from one another.

15. The semiconductor structure of claim 11, wherein the first base fin and the second base fin comprise:
a bottom portion formed from the substrate;
a middle portion over the bottom portion, the middle portion being formed from a first semiconductor layer; and
a top portion over the middle portion, the top portion being formed from a second semiconductor layer.

16. The semiconductor structure of claim 15,
wherein the bottom portion comprises silicon,
wherein the middle portion comprises silicon germanium,
wherein the top portion comprises silicon.

17. A semiconductor structure, comprising:
a substrate;
an isolation feature over the substrate;
a first base fin and a second base fin extending from the substrate and rising over the isolation feature, the first base fin and the second base fin being spaced apart from one another along a direction;
a first leakage block layer over the first base fin;
a second leakage block layer over the second base fin;
a first lopsided source/drain feature over the first leakage block layer;
a second lopsided source/drain feature over the second leakage block layer;
a bottom contact etch stop layer (CESL) over the first leakage block layer, the first lopsided source/drain feature, the second leakage block layer, and the second lopsided source/drain feature;
a bottom interlayer dielectric (ILD) layer over the bottom CESL;
a first top source/drain feature over the bottom ILD layer and being directly over the first lopsided source/drain feature; and
a second top source/drain feature over the bottom ILD layer and being directly over the second lopsided source/drain feature,
wherein the first lopsided source/drain feature comprises a first vertical sidewall extending from the first leakage block layer,
wherein the second lopsided source/drain feature comprises a second vertical sidewall extending from the second leakage block layer,
wherein the first vertical sidewall and the second vertical sidewall are facing away from one another, and
wherein the bottom CESL is disposed along the first vertical sidewall and the second vertical sidewall.

18. The semiconductor structure of claim 17,
wherein the first base fin and the second base fin are spaced apart from one another along a first direction,
wherein the first leakage block layer is disposed between a first gate spacer feature and a second gate spacer feature,
wherein the second leakage block layer is disposed between a third gate spacer feature and a fourth gate spacer feature.

19. The semiconductor structure of claim 18,
wherein top surfaces of the first gate spacer feature and the second gate spacer feature are higher than a top surface of the first leakage block layer,
wherein top surfaces of the third gate spacer feature and the fourth gate spacer feature are higher than a top surface of the second leakage block layer.

20. The semiconductor structure of claim 18,
wherein the first lopsided source/drain feature overhangs the second gate spacer feature but does not overhang the first gate spacer feature,
wherein the second lopsided source/drain feature overhangs the third gate spacer feature but does not overhang the fourth gate spacer feature.
